(19) United States
(12) Patent Application Publication
(10) Pub. No.: US 2023/0189643 A1
(43) Pub. Date: Jun. 15, 2023

(54) ORGANIC LIGHT EMITTING DIODE AND ORGANIC LIGHT EMITTING DISPLAY DEVICE INCLUDING THE SAME

(71) Applicant: LG DISPLAY CO., LTD., Seoul (KR)

(72) Inventors: In-Ae SHIN, Paju-si (KR); Hye-Li MIN, Paju-si (KR); Gi-Hwan LIM, Paju-si (KR); Jun-Yun KIM, Paju-si (KR)

(73) Assignee: LG DISPLAY CO., LTD., Seoul (KR)

(21) Appl. No.: 18/080,363

(22) Filed: Dec. 13, 2022

(30) Foreign Application Priority Data
Dec. 14, 2021 (KR) 10-2021-0178381

(51) Int. Cl. H10K 85/60; H10K 50/15; H10K 85/30; H10K 50/16; H10K 50/18

(52) U.S. Cl. CPC H10K 85/6572; H10K 50/15; H10K 50/16; H10K 50/18; H10K 85/342; H10K 85/652; H10K 85/657; H10K 85/658; H10K 85/6574; H10K 2101/30

(57) ABSTRACT

An organic light emitting diode can include a first electrode, a second electrode facing the first electrode, and a first emitting part including a first emitting material layer between the first and second electrodes, a first hole blocking layer between the second electrode and the first emitting material layer and a first intermediate functional layer between the first emitting material layer and the first hole blocking layer. The first emitting material layer includes a first compound, a second compound and a third compound. The first intermediate functional layer includes a first compound and a second compound. The second compound in the first intermediate functional layer has a core that is the same as the second compound in the first emitting material layer and has a higher LUMO energy level than the second compound in the first emitting material layer.

### CROSS-REFERENCE TO RELATED APPLICATIONS

The present application claims priority to Korean Patent Application No. 10-2021-0178381 filed in the Republic of Korea on Dec. 14, 2021, which is hereby incorporated by reference in its entirety.

### BACKGROUND

### Technical Field

The present disclosure relates to an organic light emitting diode, and more particularly, to an organic light emitting diode having high display performance and an organic light emitting display device including the organic light emitting diode.

### Discussion of the Related Art

Requirement for flat panel display devices having small occupied area is increased. Among the flat panel display devices, a technology of an organic light emitting display device, which includes an organic light emitting diode (OLED) and can be called to as an organic electroluminescent device, is rapidly developed.

The OLED emits light by injecting electrons from a cathode as an electron injection electrode and holes from an anode as a hole injection electrode into an emitting material layer, combining the electrons with the holes, generating an exciton, and transforming the exciton from an excited state to a ground state.

A fluorescent material can be used as an emitter in the OLED. However, since only singlet exciton of the fluorescent material is involved in the emission such that there is a limitation in the emitting efficiency of the fluorescent material.

### SUMMARY OF THE DISCLOSURE

Accordingly, the embodiments of the present disclosure are directed to an OLED and an organic light emitting display device that substantially obviate one or more of the problems associated with the limitations and disadvantages of the related art.

An object of the present disclosure is to provide an OLED and an organic light emitting display device having high display performance.

Additional features and aspects will be set forth in the description that follows, and in part will be apparent from the description, or can be learned by practice of the present disclosure concepts provided herein. Other features and aspects of the present disclosure concepts can be realized and attained by the structure particularly pointed out in the written description, or derivable therefrom, and the claims hereof as well as the appended drawings.

To achieve these and other advantages in accordance with the purpose of the embodiments of the present disclosure, as described herein, an aspect of the present disclosure is an organic light emitting diode including a first electrode; a second electrode facing the first electrode; and a first emitting part including a first emitting material layer between the first and second electrodes, a first hole blocking layer between the second electrode and the first emitting material layer and a first intermediate functional layer between the first emitting material layer and the first hole blocking layer, wherein the first emitting material layer includes a first compound, a second compound and a third compound, and the first intermediate functional layer includes a first compound and a second compound, and wherein the second compound in the first intermediate functional layer has a core being same as the second compound in the first emitting material layer and a higher lowest unoccupied molecular orbital (LUMO) energy level than the second compound in the first emitting material layer, wherein each of the second compound in the first emitting material layer and the second compound in the first intermediate functional layer is represented by Formula 3-1:

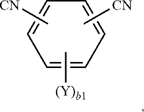

wherein b1 is an integer of 0 to 4, and Y is represented by Formula 3-2:

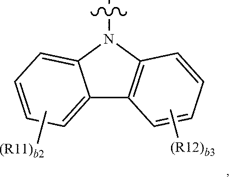

wherein each of R11 and R12 is independently selected from the group consisting of a substituted or unsubstituted C1 to C10 alkyl group, a substituted or unsubstituted C6 to C30 aryl group and a substituted or unsubstituted C5 to C30 heteroaryl group, or at least one of two adjacent R11s and two adjacent R12s are connected to each other, together with the atoms to which they are attached, to form an aromatic ring or a heteroaromatic ring, and wherein each of b2 and b3 is independently an integer of 0 to 4.

Another aspect of the present disclosure is an organic light emitting display device including a substrate including a red pixel region, a green pixel region and a blue pixel region; and an organic light emitting diode disposed on or over the substrate and in the red pixel region, the organic light emitting diode including: a first electrode; a second electrode facing the first electrode; and a first emitting part including a first emitting material layer between the first and second electrodes, a first hole blocking layer between the second electrode and the first emitting material layer and a first intermediate functional layer between the first emitting material layer and the first hole blocking layer, wherein the first emitting material layer includes a first compound, a second compound and a third compound, and the first intermediate functional layer includes a first compound and a second compound, and wherein the second compound in the first intermediate functional layer has a core being same as the second compound in the first emitting material layer and a higher LUMO energy level than the second compound in the first emitting material layer.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device of the present disclosure.

FIG. 2 is a schematic cross-sectional view of an organic light emitting display device according to a first embodiment of the present disclosure.

FIG. 3 is a schematic cross-sectional view of an OLED according to a second embodiment of the present disclosure.

FIG. 4 is an energy band diagram of a portion of an OLED according to the second embodiment of the present disclosure.

FIG. 5 is a schematic cross-sectional view of an OLED according to a third embodiment of the present disclosure.

FIG. 6 is a schematic cross-sectional view of an OLED according to a fourth embodiment of the present disclosure.

FIG. 7 is a schematic cross-sectional view of an OLED according to a fifth embodiment of the present disclosure.

FIG. 8 is a schematic cross-sectional view of an organic light emitting display device according to a sixth embodiment of the present disclosure.

FIG. 9 is a schematic cross-sectional view of an organic light emitting display device according to a seventh embodiment of the present disclosure.

### DETAILED DESCRIPTION OF THE EMBODIMENTS

Reference will now be made in detail to some of the examples and preferred embodiments, which are illustrated in the accompanying drawings. All the components of each OLED and each organic light emitting display device according to all embodiments of the present disclosure are operatively coupled and configured.

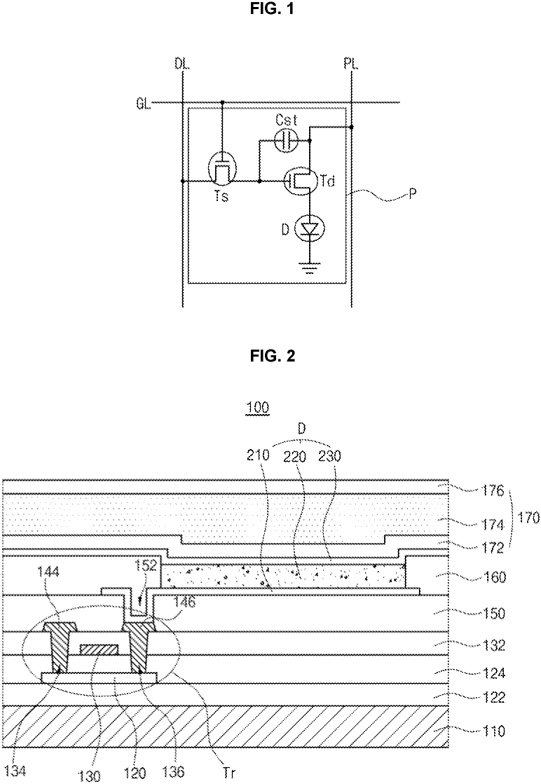

FIG. 1 is a schematic circuit diagram of an organic light emitting display device of the present disclosure.

As shown in FIG. 1, an organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region can include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to a first embodiment of the present disclosure.

As shown in FIG. 2, the organic light emitting display device 100 includes a substrate 110, a TFT Tr on or over the substrate 110, a planarization layer 150 covering the TFT Tr and an OLED D on the planarization layer 150 and connected to the TFT Tr. A red pixel region, a green pixel region and a blue pixel region can be defined on the substrate 110.

The substrate 110 can be a glass substrate or a flexible substrate. For example, the flexible substrate can be one of a polyimide (PI) substrate, a polyethersulfone (PES) substrate, a polyethylenenaphthalate (PEN) substrate, a polyethylene terephthalate (PET) substrate and a polycarbonate (PC) substrate.

A buffer layer 122 is formed on the substrate, and the TFT Tr is formed on the buffer layer 122. The buffer layer 122 can be omitted. For example, the buffer layer 122 can be formed of an inorganic insulating material, e.g., silicon oxide or silicon nitride.

A semiconductor layer 120 is formed on the buffer layer 122. The semiconductor layer 120 can include an oxide semiconductor material or polycrystalline silicon.

When the semiconductor layer 120 includes the oxide semiconductor material, a light-shielding pattern can be formed under the semiconductor layer 120. The light to the semiconductor layer 120 is shielded or blocked by the light-shielding pattern such that thermal degradation of the semiconductor layer 120 can be prevented. On the other hand, when the semiconductor layer 120 includes polycrystalline silicon, impurities can be doped into both sides of the semiconductor layer 120.

A gate insulating layer 124 is formed on the semiconductor layer 120. The gate insulating layer 124 can be formed of an inorganic insulating material such as silicon oxide or silicon nitride.

A gate electrode 130, which is formed of a conductive material, e.g., metal, is formed on the gate insulating layer 124 to correspond to a center of the semiconductor layer 120. In FIG. 2, the gate insulating layer 124 is formed on an entire surface of the substrate 110. Alternatively, the gate insulating layer 124 can be patterned to have the same shape as the gate electrode 130.

An interlayer insulating layer 132 is formed on the gate electrode 130 and over an entire surface of the substrate 110. The interlayer insulating layer 132 can be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 120. The first and second contact holes 134 and 136 are positioned at both sides of the gate electrode 130 to be spaced apart from the gate electrode 130.

The first and second contact holes 134 and 136 are formed through the gate insulating layer 124. Alternatively, when the gate insulating layer 124 is patterned to have the same shape as the gate electrode 130, the first and second contact holes 134 and 136 is formed only through the interlayer insulating layer 132.

A source electrode 144 and a drain electrode 146, which are formed of a conductive material, e.g., metal, are formed on the interlayer insulating layer 132.

The source electrode 144 and the drain electrode 146 are spaced apart from each other with respect to the gate electrode 130 and respectively contact both sides of the semiconductor layer 120 through the first and second contact holes 134 and 136.

The semiconductor layer 120, the gate electrode 130, the source electrode 144 and the drain electrode 146 constitute the TFT Tr. The TFT Tr serves as a driving element. Namely, the TFT Tr is the driving TFT Td (of FIG. 1).

In the TFT Tr, the gate electrode 130, the source electrode 144, and the drain electrode 146 are positioned over the semiconductor layer 120. Namely, the TFT Tr has a coplanar structure.

Alternatively, in the TFT Tr, the gate electrode can be positioned under the semiconductor layer, and the source and drain electrodes can be positioned over the semiconductor layer such that the TFT Tr can have an inverted staggered structure. In this instance, the semiconductor layer can include amorphous silicon.

The gate line and the data line cross each other to define the pixel region, and the switching TFT is formed to be connected to the gate and data lines. The switching TFT is connected to the TFT Tr as the driving element. In addition, the power line, which can be formed to be parallel to and spaced apart from one of the gate and data lines, and the storage capacitor for maintaining the voltage of the gate electrode of the TFT Tr in one frame can be further formed.

A planarization layer 150 is formed on an entire surface of the substrate 110 to cover the source and drain electrodes 144 and 146. The planarization layer 150 provides a flat top surface and has a drain contact hole 152 exposing the drain electrode 146 of the TFT Tr.

The OLED D is disposed on the planarization layer 150 and includes a first electrode 210, which is connected to the drain electrode 146 of the TFT Tr, an organic light emitting layer 220 and a second electrode 230. The organic light emitting layer 220 and the second electrode 230 are sequentially stacked on the first electrode 210. The OLED D is positioned in each of the red, green and blue pixel regions and respectively emits the red, green and blue light.

The first electrode 210 is separately formed in each pixel region. The first electrode 210 can be an anode and can include a transparent conductive oxide material layer, which can be formed of a conductive material, e.g., a transparent conductive oxide (TCO), having a relatively high work function, and a reflection layer. Namely, the first electrode 210 can be a reflective electrode.

Alternatively, the first electrode 210 can have a single-layered structure of the transparent conductive oxide material layer. Namely, the first electrode 210 can be a transparent electrode.

For example, the transparent conductive oxide material layer can be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO), and the reflection layer can be formed of one of silver (Ag), an alloy of Ag and one of palladium (Pd), copper (Cu), indium (In) and neodymium (Nd), and aluminum-palladium-copper (APC) alloy. For example, the first electrode 210 can have a structure of ITO/Ag/ITO or ITO/APC/ITO.

In addition, a bank layer 160 is formed on the planarization layer 150 to cover an edge of the first electrode 210. Namely, the bank layer 160 is positioned at a boundary of the pixel region and exposes a center of the first electrode 210 in the pixel region.

The organic light emitting layer 220 as an emitting unit is formed on the first electrode 210. In the OLED D in the red pixel region, the organic light emitting layer 220 include a first emitting part including a first red emitting material layer (EML), an electron blocking layer (EBL), a hole blocking layer (HBL) and an intermediate functional layer. In addition, the organic light emitting layer of the OLED D in the red pixel region can further include a second emitting part including a second red EML.

Each of the first and second emitting parts can further include at least one of a hole injection layer (HIL), a hole transporting layer (HTL), an electron transporting layer (ETL) and an electron injection layer (EIL) to have a multi-layered structure. In addition, the organic light emitting layer can further include a charge generation layer (CGL) between the first and second emitting parts.

As explained below, in the OLED D in the red pixel region, a first red EML is a fluorescent emitting layer including a first delayed fluorescent compound and a fluorescent compound. The intermediate function layer includes a second delayed fluorescent compound and is positioned between the first red EML and the HBL. The second delayed fluorescent compound has the same chemical structure as the first delayed fluorescent compound and a lowest unoccupied molecular orbital (LUMO) energy level being higher than the first delayed fluorescent compound. As a result, the emitting performance of the OLED D is improved.

The second electrode 230 is formed over the substrate 110 where the organic light emitting layer 220 is formed. The second electrode 230 covers an entire surface of the display area and can be formed of a conductive material having a relatively low work function to serve as a cathode. For example, the second electrode 230 can be formed of aluminum (Al), magnesium (Mg), calcium (Ca), silver (Ag) or their alloy, e.g., Mg—Ag alloy (MgAg). The second electrode 230 can have a thin profile, e.g., 10 to 30 nm, to be transparent (or semi-transparent).

Alternatively, the first electrode 210 can be a transparent electrode, and the second electrode 230 can be a reflective electrode.

The OLED D can further include a capping layer on the second electrode 230. The emitting efficiency of the OLED D and/or the organic light emitting display device 100 can be further improved by the capping layer.

An encapsulation film (or an encapsulation layer) 170 is formed on the second electrode 230 to prevent penetration of moisture into the OLED D. The encapsulation film 170 includes a first inorganic insulating layer 172, an organic insulating layer 174 and a second inorganic insulating layer 176 sequentially stacked, but it is not limited thereto.

The organic light emitting display device 100 can include a color filter corresponding to the red, green and blue pixel regions. For example, the color filter can be positioned on or over the OLED D or the encapsulation film 170.

In addition, the organic light emitting display device 100 can further include a cover window on or over the encapsulation film 170 or the color filter. In this instance, the substrate 110 and the cover window have a flexible property such that a flexible organic light emitting display device can be provided.

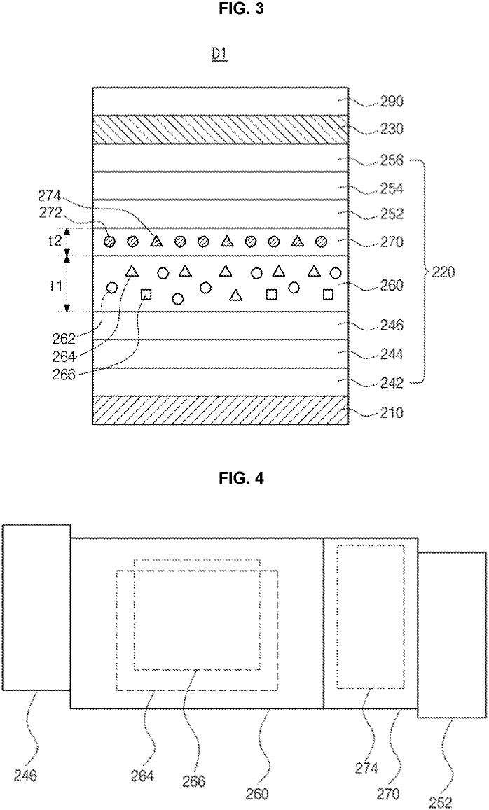

FIG. 3 is a schematic cross-sectional view of an OLED according to a second embodiment of the present disclosure.

As shown in FIG. 3, the OLED D1 includes the first electrode 210, the second electrode 230 facing the first electrode 210, and the organic light emitting layer 220 therebetween. The organic light emitting layer 220 includes an EML 260, an EBL 246, an HBL 252 and an intermediate functional layer 270. In addition, the OLED D1 can further include a capping layer 290 for enhancing (improving) an emitting efficiency.

The organic light emitting display device can include a red pixel region, a green pixel region and a blue pixel region, and the OLED D1 is positioned in the red pixel region.

The first electrode 210 can be anode, and the second electrode 230 can be a cathode. The first electrode 210 is a reflective electrode, and the second electrode 230 is a transparent electrode (or a semi-transparent electrode). For example, the first electrode 210 can have a structure of ITO/Ag/ITO, and the second electrode 230 can be formed of MgAg or Al. Namely, the first electrode 210 can have a first transmittance, and the second electrode 230 can have a second transmittance greater than the first transmittance.

Alternatively, the first electrode 210 can be a transparent electrode, and the second electrode 230 can be a reflective electrode.

The EBL 246 is positioned between the first electrode 210 and the EML 260, and the HBL 252 is positioned between the second electrode 230 and the EML 260. The intermediate functional layer 270 is positioned between the HBL 252 and the EML 260. Namely, one surface (side) of the EML 260 contacts the EBL 246, and the other surface of the EML 260 contacts the intermediate functional layer 270 with being spaced apart from the HBL 252. One surface and the other surface of the intermediate functional layer 270 respectively contact the EML 260 and the HBL 252.

The EML 260 includes a first compound 262, a second compound 264 and a third compound 266. The first compound 262 acts as a host, the second compound 264 acts as an auxiliary host (auxiliary dopant), and the third compound 266 acts as a dopant (emitter). The second compound 264 is a delayed fluorescent compound, and the third compound 266 is a fluorescent compound.

The intermediate functional layer 270 includes a first compound 272 and a second compound 274.

Each of the first compound 262 in the EML 260 and the first compound 272 in the intermediate functional layer 270 is represented by Formula 1.

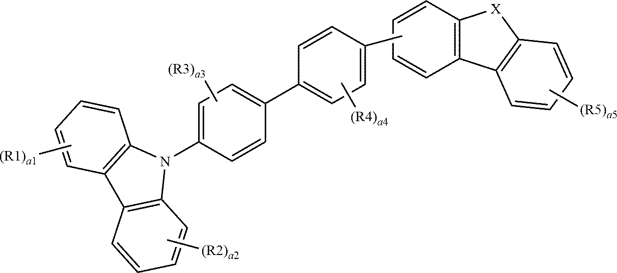

In Formula 1, each of R1, R2, R3, R4 and R5 is independently selected from the group consisting of a substituted or unsubstituted C1 to C10 alkyl group, a substituted or unsubstituted C6 to C30 arylene group and a substituted or unsubstituted C5 to C30 heteroarylene group, and each of a1, a2, a3, a4 and a5 is independently an integer of 0 to 4. X is NR6, O or S, and R6 is selected from the group consisting of hydrogen, a substituted or unsubstituted C1 to C10 alkyl group, a substituted or unsubstituted C6 to C30 arylene group and a substituted or unsubstituted C5 to C30 heteroarylene group.

Namely, the first compound 262 in the EML 260 and the first compound 272 in the intermediate functional layer 270 have the same chemical structure and can be same or different.

In the present disclosure, the C6 to C30 aryl group (or C6 to C30 arylene group) can be selected from the group consisting of phenyl, biphenyl, terphenyl, naphthyl, anthracenyl, pentanenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, the C5 to C30 heteroaryl group can be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, quinolinyl, purinyl, phthalazinyl, quinoxalinyl, benzoquinolinyl, benzoisoquinolinyl, benzoquinazolinyl, benzoquinoxalinyl, acridinyl, phenanthrolinyl, perimidinyl, phenanthridinyl, pteridinyl, cinnolinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In the present disclosure, without specific definition, a substituent of an alkyl group, an aryl group and/or a heteroaryl group can be at least one of deuterium, tritium, a cyano group, halogen, a C1 to C10 alkyl group, a C1 to C10 alkoxy group and a C6 to C30 aryl group, wherein a C6 to C30 aryl group can be optionally further substituted with a C1 to C10 alkyl group.

A group described as “substituted or unsubstituted” can be substituted with one or more groups defined herein (as valency allows).

Each of the first compound 262 in the EML 260 and the first compound 272 in the intermediate functional layer 270 can be one of the compounds in Formula 2. [Formula 2]

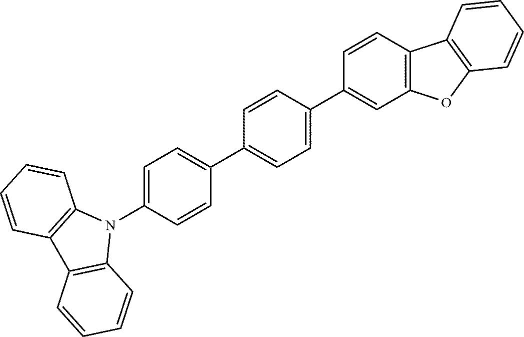 [SMILES: c1ccc2c(c1)oc1cc(-c3ccc(-c4ccc(-n5c6ccccc6c6ccccc65)cc4)cc3)ccc12]

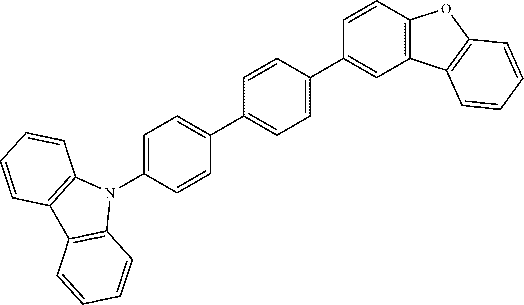 [SMILES: c1ccc2c(c1)oc1ccc(-c3ccc(-c4ccc(-n5c6ccccc6c6ccccc65)cc4)cc3)cc12]

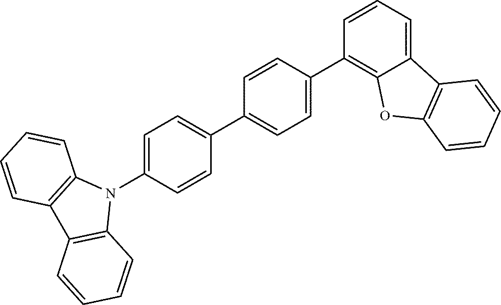 [SMILES: c1ccc2c(c1)oc1c(-c3ccc(-c4ccc(-n5c6ccccc6c6ccccc65)cc4)cc3)cccc12]

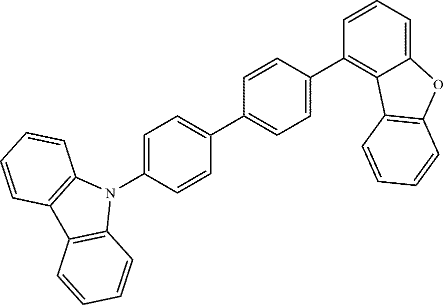 [SMILES: c1ccc2c(c1)oc1cccc(-c3ccc(-c4ccc(-n5c6ccccc6c6ccccc65)cc4)cc3)c12]

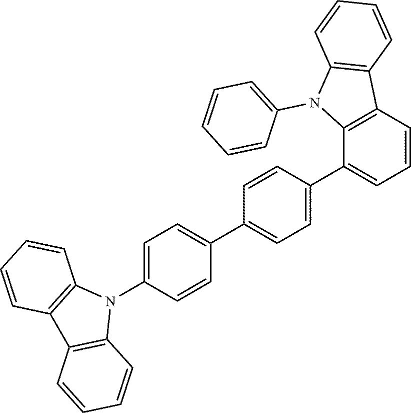 [SMILES: c1ccc(-n2c3ccccc3c3cccc(-c4ccc(-c5ccc(-n6c7ccccc7c7ccccc76)cc5)cc4)c32)cc1]

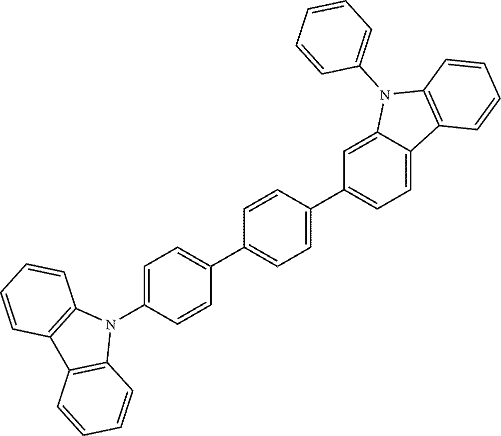 [SMILES: c1ccc(-n2c3ccccc3c3ccc(-c4ccc(-c5ccc(-n6c7ccccc7c7ccccc76)cc5)cc4)cc32)cc1]

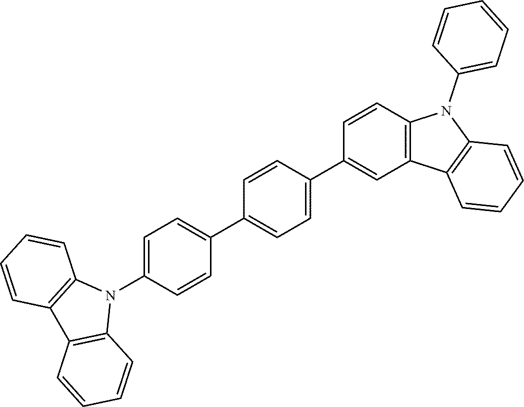 [SMILES: c1ccc(-n2c3ccccc3c3cc(-c4ccc(-c5ccc(-n6c7ccccc7c7ccccc76)cc5)cc4)ccc32)cc1]

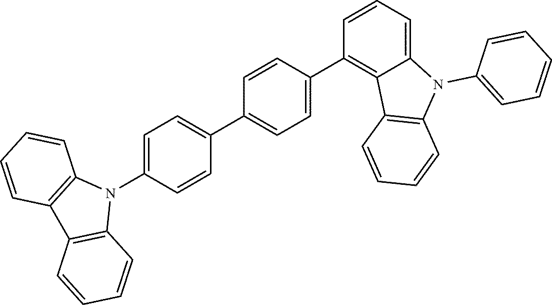 [SMILES: c1ccc(-n2c3ccccc3c3c(-c4ccc(-c5ccc(-n6c7ccccc7c7ccccc76)cc5)cc4)cccc32)cc1]

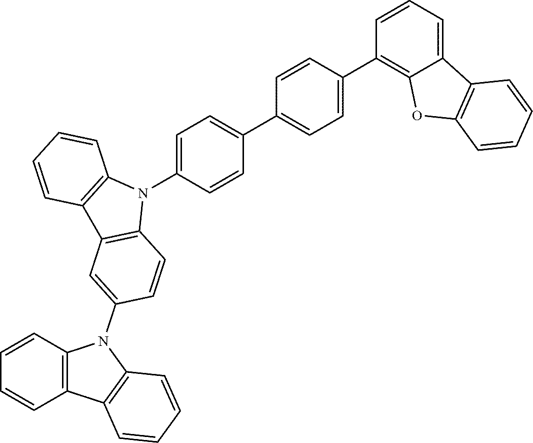 [SMILES: c1ccc2c(c1)oc1c(-c3ccc(-c4ccc(-n5c6ccccc6c6cc(-n7c8ccccc8c8ccccc87)ccc65)cc4)cc3)cccc12]

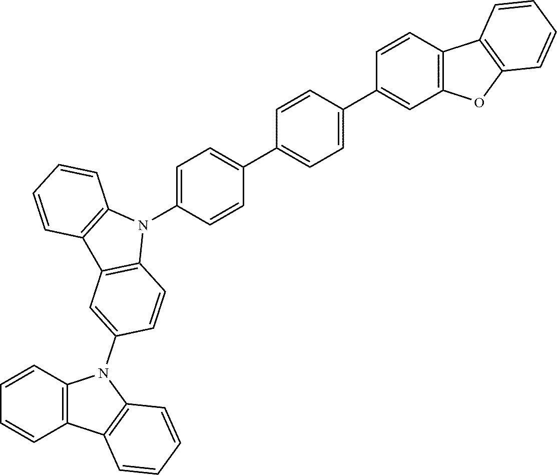 [SMILES: c1ccc2c(c1)oc1cc(-c3ccc(-c4ccc(-n5c6ccccc6c6cc(-n7c8ccccc8c8ccccc87)ccc65)cc4)cc3)ccc12]

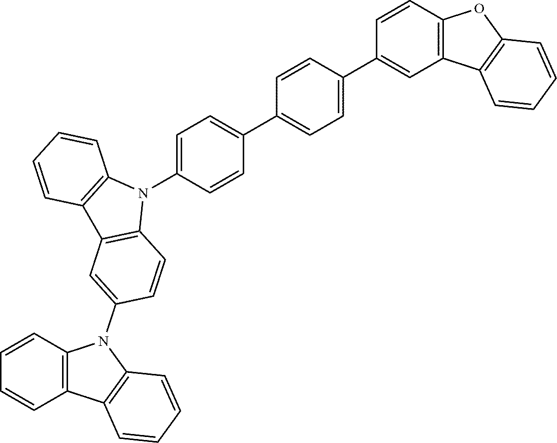 [SMILES: c1ccc2c(c1)oc1ccc(-c3ccc(-c4ccc(-n5c6ccccc6c6cc(-n7c8ccccc8c8ccccc87)ccc65)cc4)cc3)cc12]

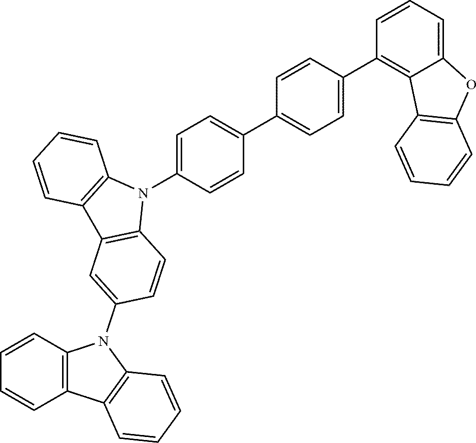 [SMILES: c1ccc2c(c1)oc1cccc(-c3ccc(-c4ccc(-n5c6ccccc6c6cc(-n7c8ccccc8c8ccccc87)ccc65)cc4)cc3)c12]

Each of the second compound 264 in the EML 260 and the second compound 274 in the intermediate functional layer 270 is represented by Formula 3-1, and the second compound 264 in the EML 260 and the second compound 274 in the intermediate functional layer 270 are different.

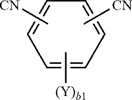

In Formula 3-1, Y is represented by Formula 3-2, and b1 is an integer of 1 to 4. When b1 is 2 or more, Y is same or different.

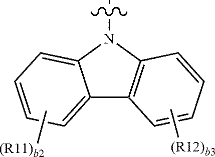

In Formula 3-2, each of R11 and R12 is independently selected from the group consisting of a substituted or unsubstituted C1 to C10 alkyl group, a substituted or unsubstituted C6 to C30 aryl group and a substituted or unsubstituted C5 to C30 heteroaryl group, or at least one of two adjacent R11 s and two adjacent R12s is connected to each other to form an aromatic ring or a heteroaromatic ring. In addition, each of b2 and b3 is independently an integer of 0 to 4.

For example, b1 can be 4, and each of R11 and R12 can be independently selected from the group consisting of a C1 to C10 alkyl group, e.g., methyl, a C6 to C30 aryl group, e.g., phenyl, a C5 to C30 heteroaryl group, e.g., carbazolyl, or at least one of two adjacent R11s and two adjacent R12s is connected to each other to form a heteroaromatic ring.

Namely, the second compound 264 in the EML 260 and the second compound 274 in the intermediate functional layer 270 have the same core and are different.

The second compound 274 in the intermediate functional layer 270 has an LUMO energy level being higher than the second compound 264 in the EML 260. For example, a difference between an LUMO energy level of the second compound 274 in the intermediate functional layer 270 and an LUMO energy level of the second compound 264 in the EML 260 can be 0.5 eV or less.

The LUMO energy level of the second compound 264 in the EML 260 can be lower than 3.0 eV.

The LUMO energy level can be determined by measurement of the HOMO energy level and bandgap. The LUMO energy level is equal to the HOMO energy level - the bandgap (i.e., LUMO=HOMO-bandgap). The HOMO energy level can be determined by preparation of a single film (neat film) with a thickness of 50 nm and measurement with a photoelectron spectrophotometer in air (for example, AC3). The bandgap can be calculated from a tangential wavelength in an edge by measuring UV-vis in a single film with a thickness of 50 nm (for example, SCINCO / S-3100). The bandgap is equal to 1239.85 divided by the tangential wavelength (i.e., bandgap=1239.85/(tangential wavelength)).

Referring to FIG. 4, which is an energy band diagram of a portion of an OLED according to the second embodiment of the present disclosure, an LUMO energy level of the second compound 274 in the intermediate functional layer 270 is higher than an LUMO energy level of the second compound 264 in the EML 260. A highest occupied molecular orbital (HOMO) of the second compound 274 in the intermediate functional layer 270 is equal to or different from a HOMO energy level of the second compound 264 in the EML 260. In addition, in the EML 260, an LUMO energy level of the third compound 266 being a fluorescent dopant is equal to or higher than that of the second compound 264, and a HOMO energy level of the third compound 266 is higher than that of the second compound 264. Moreover, a HOMO energy level of the third compound 266 is higher than a HOMO energy level of the second compound 274 in the intermediate functional layer 270.

The second compound 264 in the EML 260 is one of the compounds in Formula 4, and the second compound 274 in the intermediate functional layer 270 is another one of the compounds in Formula 4. [Formula 4]

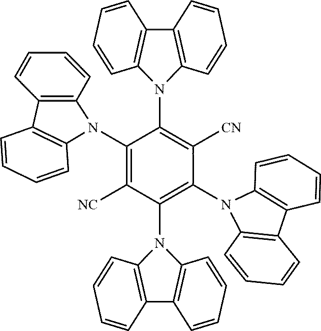

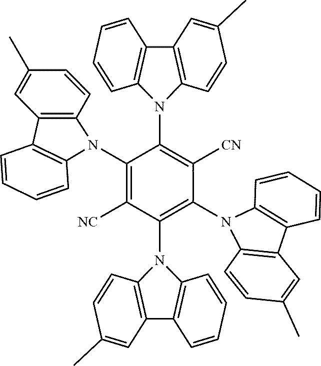

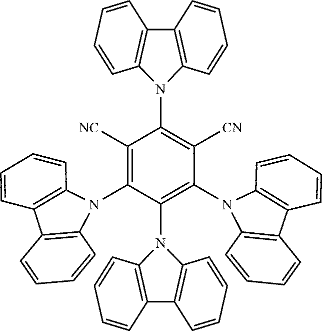

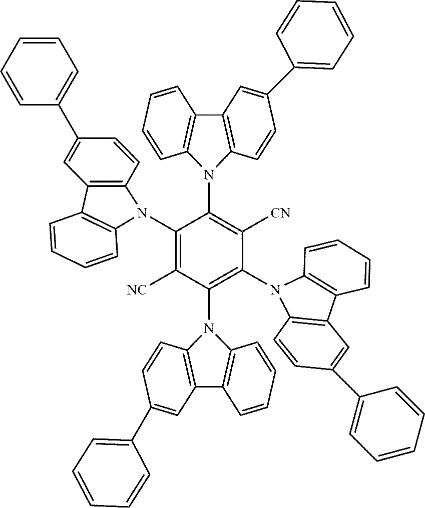

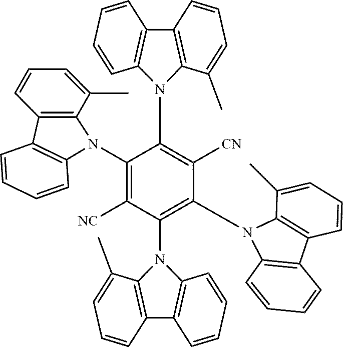

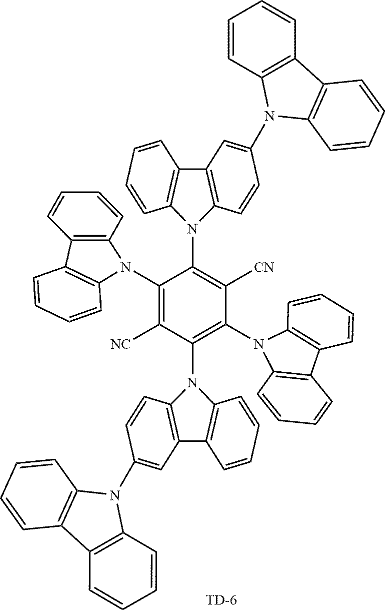

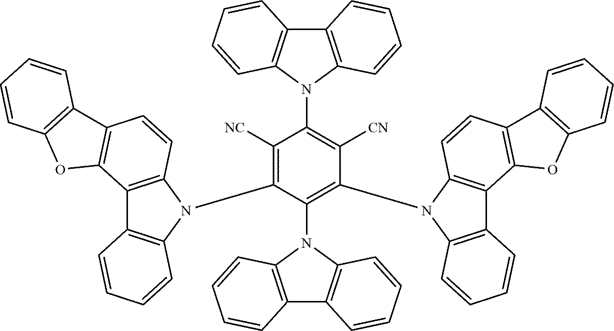

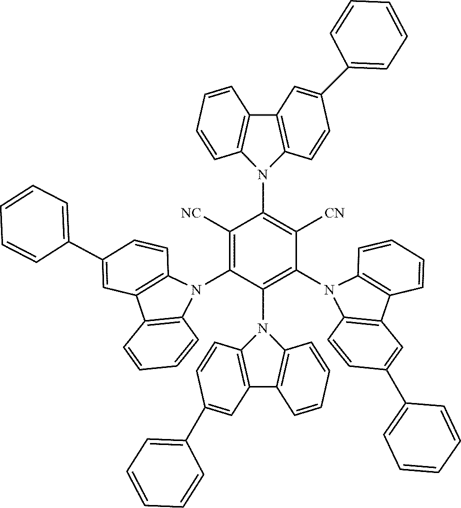

For example, the second compound 264 in the EML 260 can be represented by Formula 3a, and the second compound 274 in the intermediate functional layer 270 can be represented by Formula 3b.

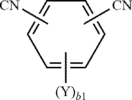

In Formula 3a, Y is represented by Formula 3-2, and the definition of b1 is same as that in Formula 3-1.

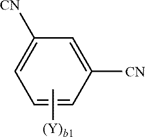

In Formula 3b, Y is represented by Formula 3-2, and the definition of b1 is same as that in Formula 3-1.

Namely, the second compound 264 in the EML 260 has a structure including two cyano groups and at least one substituted or unsubstituted carbazole group, which are connected to a benzene moiety, and two cyano groups are presented in a para-position.

On the other hand, the second compound 274 in the intermediate functional layer 270 has a structure including two cyano groups and at least one substituted or unsubstituted carbazole group, which are connected to a benzene moiety, and two cyano groups are presented in a meta-position.

In one embodiment, each of the second compound 264 in the EML 260 and the second compound 274 in the intermediate functional layer 270 is represented by Formula 3-3.

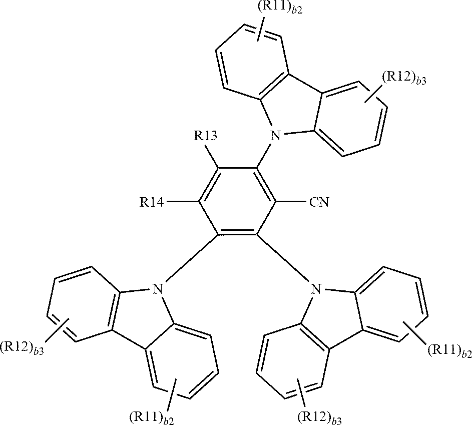

In Formula 3-3, one of R13 and R14 is CN, and the other one of R13 and R14 is represented by Formula 3-2.

For example, in the second compound 264 in the EML 260, R14 is CN, and R13 is represented by Formula 3-2. In the second compound 274 in the intermediate functional layer 270, R13 is the second compound 274 in the intermediate functional layer 270, and R14 is CN.

For example, the second compound 264 in the EML 260 can be one of the compounds in Formula 4a, and the second compound 274 in the intermediate functional layer 270 can be one of the compounds in Formula 4b. [Formula 4a]

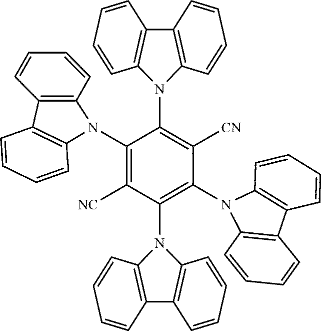

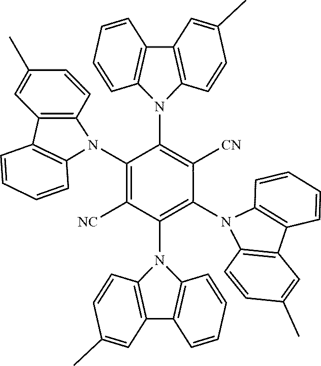

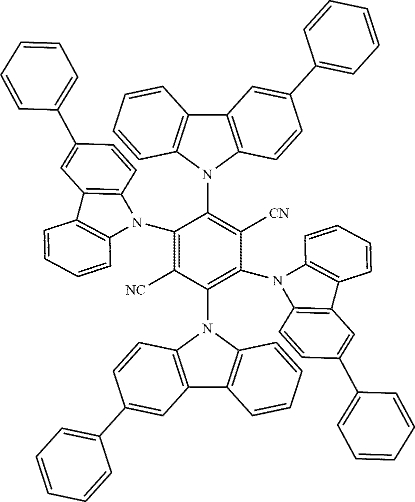 [SMILES: N#Cc1c(-n2c3ccccc3c3cc(-c4ccccc4)ccc32)c(-n2c3ccccc3c3cc(-c4ccccc4)ccc32)c(C#N)c(-n2c3ccccc3c3cc(-c4ccccc4)ccc32)c1-n1c2ccccc2c2cc(-c3ccccc3)ccc21]

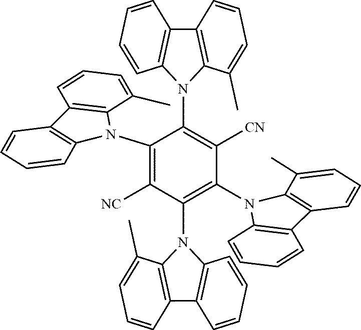 [SMILES: Cc1cccc2c3ccccc3n(-c3c(C#N)c(-n4c5ccccc5c5cccc(C)c54)c(-n4c5ccccc5c5cccc(C)c54)c(C#N)c3-n3c4ccccc4c4cccc(C)c43)c12]

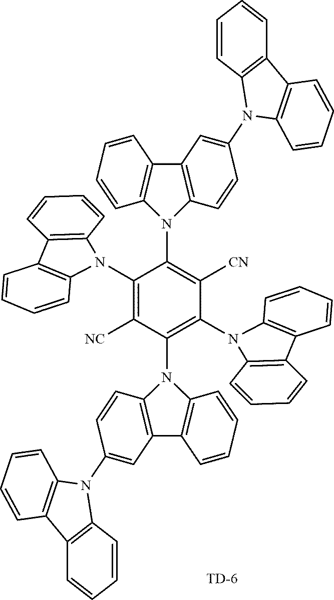 [SMILES: N#Cc1c(-n2c3ccccc3c3ccccc32)c(-n2c3ccccc3c3cc(-n4c5ccccc5c5ccccc54)ccc32)c(C#N)c(-n2c3ccccc3c3ccccc32)c1-n1c2ccccc2c2cc(-n3c4ccccc4c4ccccc43)ccc21 ; "TD-6"]

[Formula 4b]

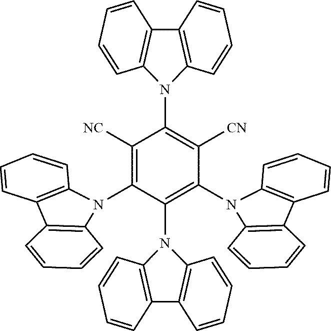 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

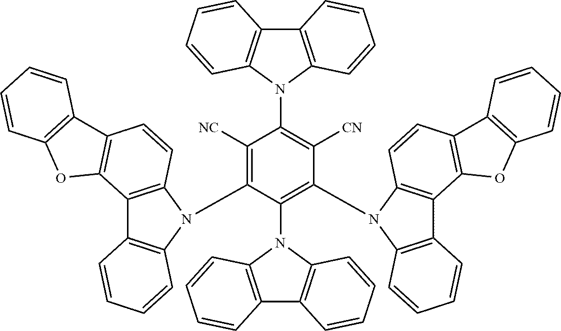

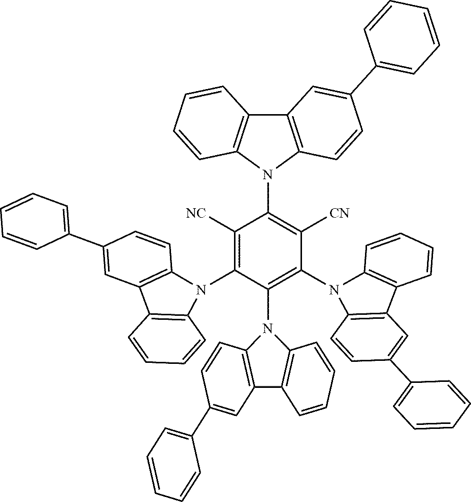 [SMILES: N#Cc1c(-n2c3ccccc3c3cc(-c4ccccc4)ccc32)c(C#N)c(-n2c3ccccc3c3cc(-c4ccccc4)ccc32)c(-n2c3ccccc3c3cc(-c4ccccc4)ccc32)c1-n1c2ccccc2c2cc(-c3ccccc3)ccc21]

The third compound 266 in the EML 260 has an energy band gap “Eg” of 1.8 to 2.2 eV and an LUMO energy level being lower than -3.0 eV. In addition, the third compound 266 in the EML 260 has an emission wavelength range of 580 to 650 nm, e.g., 610 to 630 nm.

The third compound 266 in the EML 260 is represented by Formula 5.

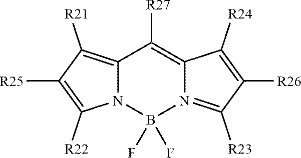

In Formula 5, each of R21, R22, R23 and R24 is independently selected from a substituted or unsubstituted C6 to C30 aryl group, and each of R25, R26 and R27 is independently selected from the group consisting of hydrogen, deuterium, a substituted or unsubstituted C1 to C10 alkyl group, a substituted or unsubstituted C6 to C30 aryl group and a substituted or unsubstituted C5 to C30 heteroaryl group.

For example, each of R21, R22, R23 and R24 can be phenyl unsubstituted or substituted with a C1 to C10 alkyl group, e.g., methyl or tert-butyl. In addition, each of R25 and R26 can be hydrogen, and R27 can be selected from a C6 to C30 aryl group, e.g., phenyl, unsubstituted or substituted with at least one of a C1 to C10 alkoxy group, e.g., methoxy, and a C6 to C30 aryl group, e.g., tert-butyl phenyl, and a substituted or unsubstituted C5 to C30 heteroaryl group, e.g., dibenzofuranyl or thiophenyl.

The third compound 266 in the EML 260 can be one of the compounds in Formula 6. [Formula 6]

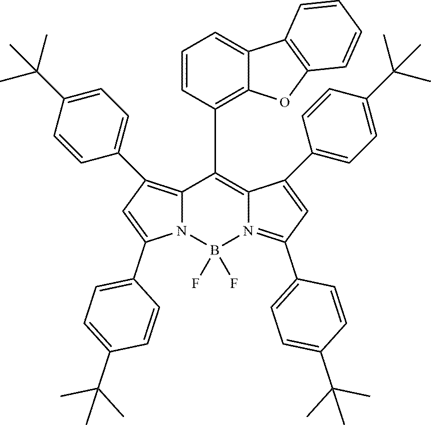

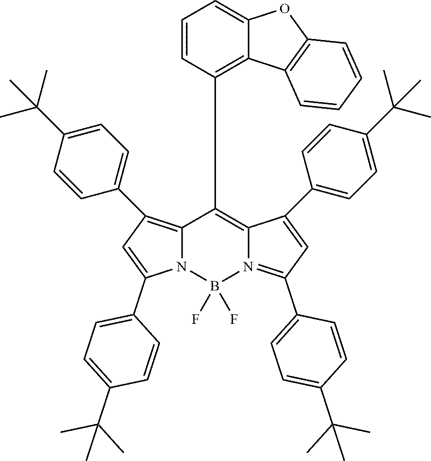

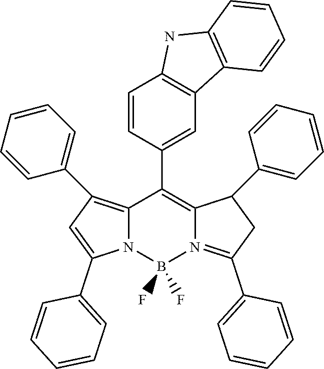

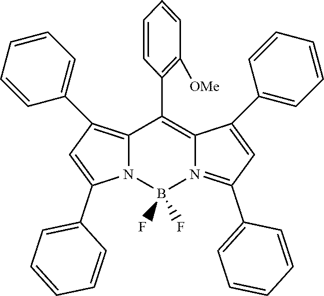

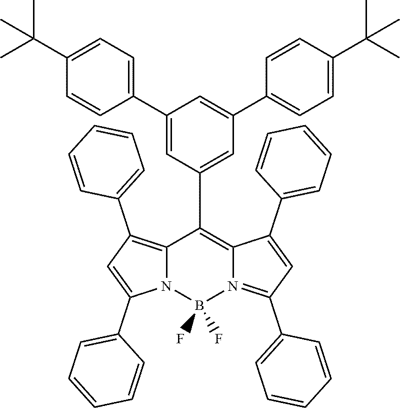

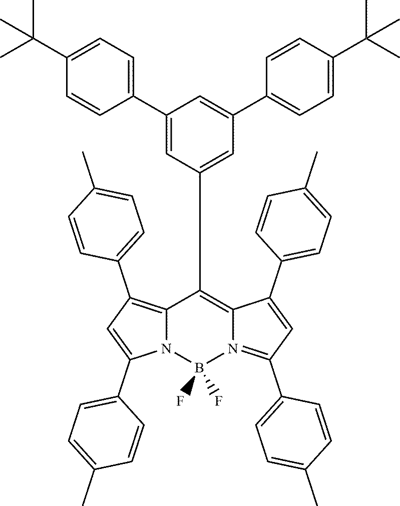

In the EML 260, each of a first weight % of the first compound 262 and a second weight % of the second compound 264 is greater than a third weight % of the third compound 266. The second weight % of the second compound 264 can be same as or different from the first weight % of the first compound 262. The EML 260 consists of the first to third compounds 262, 264 and 266, and a summation of the first weight % of the first compound 262, the second weight % of the second compound 264 and the third weight % of the third compound 266 in the EML 260 is 100 wt.%.

In addition, in the EML 260, a triplet energy level of the second compound 264 is lower than that of the first compound 262 and higher than that of the third compound 266.

In the intermediate functional layer 270, a fourth weight % of the first compound 272 is greater than a fifth weight % of the second compound 274. The intermediate functional layer 270 consists of the first and second compounds 272 and 274, and a summation of the fourth weight % of the first compound 272 and the fifth weight % of the second compound 274 in the intermediate functional layer 270 is 100 wt%.

The second weight % of the second compound 264 in the EML 260 is greater than the fifth weight % of the second compound 274 in the intermediate functional layer 270. For example, the second weight % of the second compound 264 in the EML 260 can be 40 wt% or more and 60 wt% or less, and the fifth weight % of the second compound 274 in the intermediate functional layer 270 can be 1 wt% or more and 10 wt% or less.

The EML 260 has a first thickness t1, and the intermediate functional layer 270 has a second thickness t2 being smaller than the first thickness t1. The second thickness t2 can be 40% or less of the first thickness t1. For example, the second thickness t2 can be 10 Å or more and 100 Å or less.

The EML 260 is a layer for emitting light, while the intermediate functional layer 270 is a layer for transporting an electron into the EML 260 and preventing an exciton transfer from the EML 260 and the HBL 252.

The EBL 246 can include the compound in Formula 7.

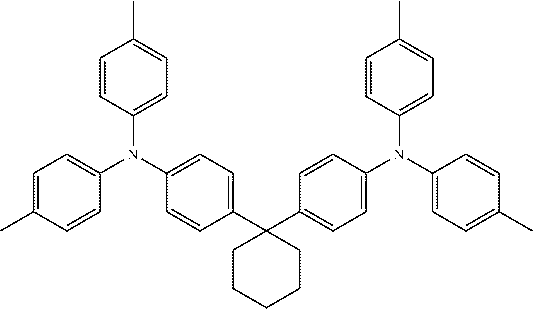

Alternatively, the EBL 246 can include at least one of compounds selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene(mCP), 3,3′-bis(N-carbazolyl)-1,1′-biphenyl(mCBP), CuPc, N,N′-bis[4-[bis(3-methylphenyl)amino]phenyl]-N,N′-diphenyl-[1,1′-biphenyl]-4,4′-diamine(DNTPD), TDAPB, DCDPA and 2,8-bis(9-phenyl-9H-carbazol-3-yl)dibenzo[b,d]thiophene). The EBL 246 can have a thickness of 5 to 20 nm. For example, the thickness of the EBL 246 can be equal to or smaller than the second thickness t2 of the intermediate functional layer 270.

The HBL 252 includes a material having a HOMO energy level being lower than the EML 260 and the intermediate functional layer 270.

The HBL 252 can include the compound in Formula 8.

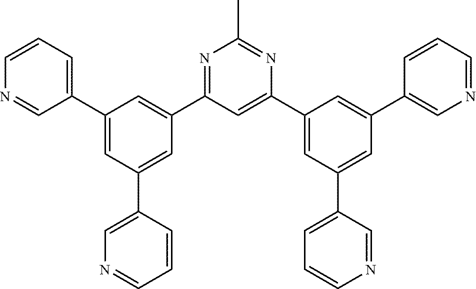 [SMILES: Cc1nc(-c2cc(-c3cccnc3)cc(-c3cccnc3)c2)cc(-c2cc(-c3cccnc3)cc(-c3cccnc3)c2)n1]

Alternatively, the HBL 252 can include at least one of compounds selected from the group consisting of BCP, BAlq, Alq3, PBD, spiro-PBD, Liq, bis-4,6-(3,5-di-3-pyridylphenyl)-2-methylpyrimidine(B3PYMPM), bis[2-(diphenylphosphino)phenyl]ether oxide(DPEPO), 9-(6-9H-carbazol-9-yl)pyridine-3-yl)-9H-3,9′-bicarbazole and TSPO1.

The HBL 252 can have a thickness of 5 to 20 nm. For example, the thickness of the HBL 252 can be equal to or smaller than the second thickness t2 of the intermediate functional layer 270.

As illustrated above, the EBL 246 contacts a first surface of the EML 260, i.e., a surface at a side of the first electrode 210, and the HBL 260 is spaced apart from a second surface of the EML 260, i.e., a surface at a side of the second electrode 230, and contacts the intermediate functional layer 270.

The OLED D1 can further include at least one of an HTL 244 between the first electrode 210 and the EBL 246 and an ETL 254 between the second electrode 230 and the HBL 252.

In addition, the OLED D1 can further include at least one of an HIL 242 between the first electrode 210 and the HTL 244 and an ElL 256 between the second electrode 230 and the ETL 254.

For example, the HTL 244 can include one of the compounds in Formula 9.

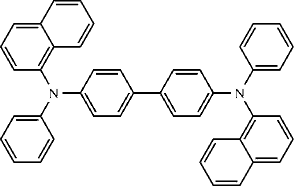 [SMILES: c1ccc(N(c2ccc(-c3ccc(N(c4ccccc4)c4cccc5ccccc45)cc3)cc2)c2cccc3ccccc23)cc1]

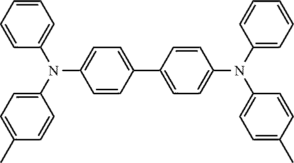 [SMILES: Cc1ccc(N(c2ccccc2)c2ccc(-c3ccc(N(c4ccccc4)c4ccc(C)cc4)cc3)cc2)cc1]

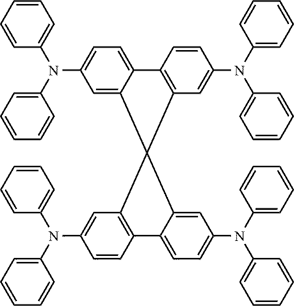 [SMILES: c1ccc(N(c2ccccc2)c2ccc3c(c2)C2(c4cc(N(c5ccccc5)c5ccccc5)ccc4-3)c3cc(N(c4ccccc4)c4ccccc4)ccc3-c3ccc(N(c4ccccc4)c4ccccc4)cc32)cc1]

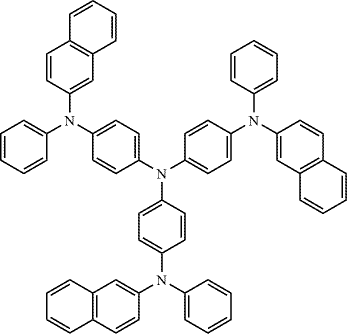 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

Alternatively, the HTL 244 can include one of the compounds selected from the group consisting of N,N′-diphenyl-N,N′-bis(3-methylphenyl)-1,1′-biphenyl-4,4′-diamine; TPD), N,N′-diphenyl-N,N′-bis(1-naphthyl)-1,1′-biphenyl-4,4″-diamine(NPB; NPD), 4,4′-bis(N-carbazolyl)-1,1′-biphenyl(CBP), poly[N,N′-bis(4-butylphenyl)-N,N′-bis(phenyl)-benzidine](Poly-TPD), (poly[(9,9-dioctylfluorenyl-2,7-diyl)-co-(4,4′-(N-(4-sec-butylphenyl)diphenylamine))] (TFB), di-[4-(N,N-di-p-tolyl-amino)-phenyl]cyclohexane(TAPC), 3,5-di(9H-carbazol-9-yl)-N,N-diphenylaniline(DCDPA), N-(biphenyl-4-yl)-9,9-dimethyl-N-(4-(9-phenyl-9H-carbazol-3-yl)phenyl)-9H-fluoren-2-amine and N-(biphenyl-4-yl)-N-(4-(9-phenyl-9H-carbazol-3-yl)phenyl)biphenyl-4-amine.

The HIL 242 can include one of the compound in Formula 9 and the compound in Formula 10 as a dopant. In HIL 242, the compound in Formula 10 can have a weight % of about 1 to 10.

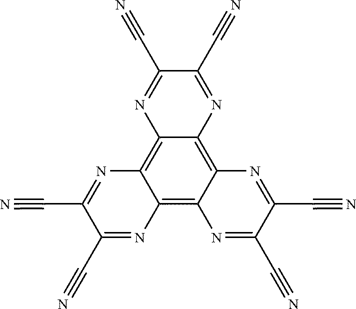 [SMILES: N#Cc1nc2c3nc(C#N)c(C#N)nc3c3nc(C#N)c(C#N)nc3c2nc1C#N]

Alternatively, the HIL 242 can include at least one of the compounds selected from the group consisting of 4,4′,4″-tris(3-methylphenylamino)triphenylamine (MTDATA), 4,4′,4″-tris(N,N-diphenyl-amino)triphenylamine(NATA), 4,4′,4″-tris(N-(naphthalene-1-yl)-N-phenyl-amino)triphenylamine(1T-NATA), 4,4′,4″-tris(N-(naphthalene-2-yl)-N-phenyl-amino)triphenylamine(2T-NATA), copper phthalocyanine(CuPc), tris(4-carbazoyl-9-yl-phenyl)amine(TCTA), NPB (or NPD), 1,4,5,8,9,11-hexaazatriphenylenehexacarbonitrile(dipyrazino[2,3-f:2′3′-h]quinoxaline-2,3,6,7,10,11-hexacarbonitrile; HAT-CN), 1,3,5-tris[4-(diphenylamino)phenyl]benzene(TDAPB), poly(3,4-ethylenedioxythiphene)polystyrene sulfonate(PEDOT/PSS) and N-(biphenyl-4-yl)-9,9-dimethyl-N-(4-(9-phenyl-9H-carbazol-3-yl)phenyl)-9H-fluoren-2-amine.

The HTL 254 can include at least one of the compounds in Formula 11.

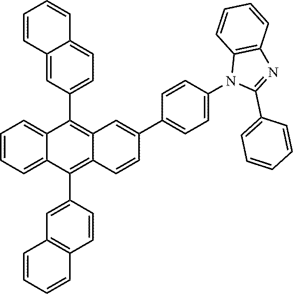 [SMILES: c1ccc(-c2nc3ccccc3n2-c2ccc(-c3ccc4c(-c5ccc6ccccc6c5)c5ccccc5c(-c5ccc6ccccc6c5)c4c3)cc2)cc1]

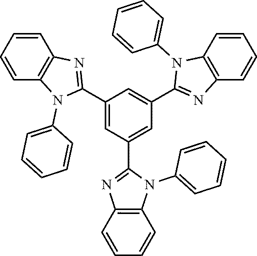 [SMILES: c1ccc(-n2c(-c3cc(-c4nc5ccccc5n4-c4ccccc4)cc(-c4nc5ccccc5n4-c4ccccc4)c3)nc3ccccc32)cc1]

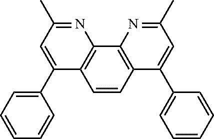 [SMILES: Cc1cc(-c2ccccc2)c2ccc3c(-c4ccccc4)cc(C)nc3c2n1]

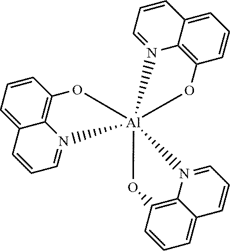

Alternatively, the ETL 254 can include one of an oxadiazole-containing compound, a triazole-containing compound, a phenanthroline-containing compound, a benzoxazole-containing compound, a benzothiazole-containing compound, a benzimidazole-containing compound and a triazine-containing compound. For example, the ETL 254 can include the compound selected from the group consisting of tris-(8-hydroxyquinoline aluminum(Alq₃), 2-biphenyl-4-yl-5-(4-t-butylphenyl)-1,3,4-oxadiazole(PBD), spiro-PBD, lithium quinolate(Liq), 1,3,5-tris(N-phenylbenzimidazol-2-yl)benzene(TPBi), bis(2-methyl-8-quinolinolato-N1,O8)-(1,1′-biphenyl-4-olato)aluminum(BAlq), 4,7-diphenyl-1,10-phenanthroline(Bphen), 2,9-bis(naphthalene-2-yl)4,7-diphenyl-1,10-phenanthroline(NBphen), 2,9-dimethyl-4,7-diphenyl-1,10-phenathroline(BCP), 3-(4-biphenyl)-4-phenyl-5-tert-butylphenyl-1,2,4-triazole(TAZ), 4-(naphthalen-1-yl)-3,5-diphenyl-4H-1,2,4-triazole(NTAZ), 1,3,5-tri(p-pyrid-3-yl-phenyl)benzene(TpPyPB), 2,4,6-tris(3′-(pyridin-3-yl)biphenyl-3-yl)1,3,5-triazine(TmPPPyTz), Poly[9,9-bis(3′-((N,N-dimethyl)-N-ethylammonium)-propyl)-2,7-fluorene]-alt-2,7-(9,9-dioctylfluorene)](PFNBr), tris(phenylquinoxaline(TPQ) and diphenyl-4-triphenylsilyl-phenylphosphine oxide(TSPO1).

The EIL 256 includes an alkali halide compound, such as LiF, CsF, NaF, or BaF₂, but it is not limited thereto.

The capping layer 290 is positioned on or over the second electrode 230 and can include one of the compounds in Formula 9.

In the OLED D1 of the present disclosure, the EML 260 includes the second compound 264 having high quantum efficiency and the third compound 266 having narrow FWHM so that the OLED D1 provides hyper-fluorescence.

In addition, since the intermediate functional layer 270, which includes the second compound 274 having the same core as the second compound 264 in the EML 260 and a higher LUMO energy level than the second compound 264 in the EML 260, is disposed between the EML 260 and the HBL 252, the driving voltage and the FWHM of the OLED D1 are reduced, and the emitting efficiency (luminance) of the OLED D1 is improved.

Namely, the charge balance in the EML 260 is improved by the intermediate functional layer 270, and the exciton quenching problem resulting from the exciton transfer from the EML 260 into the HBL 252 is prevented. As a result, the emitting property of the OLED D1 is improved.

Moreover, since an exciton generation zone, i.e., a recombination zone of the hole and electron, which is presented at an interface between the EML 260 and the HBL 252 in the related art OLED, is shifted toward the EBL 246, the emitting property of the OLED D1 is further improved.

Furthermore, since the second compound 264 as a first delayed fluorescent compound in the EML 260 and the second compound 274 as a second delayed fluorescent compound in the intermediate functional layer 270 have the same core and similar property, an interface property between the EML 260 and the intermediate functional layer 270 is improved so that the emitting property of the OLED D1 is further improved.

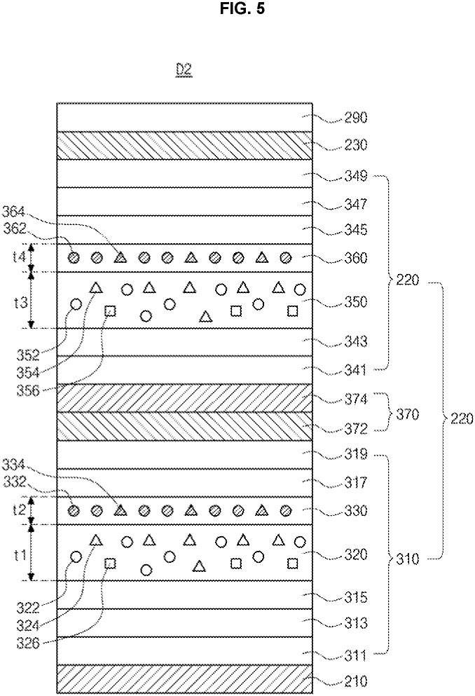

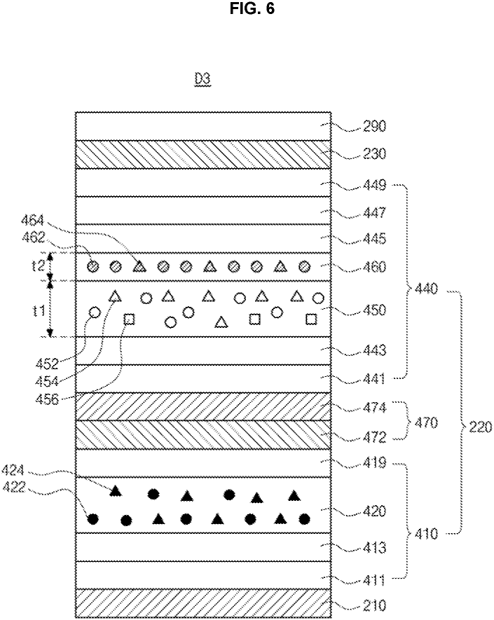

FIG. 5 is a schematic cross-sectional view of an OLED according to a third embodiment of the present disclosure.

As shown in FIG. 5, the OLED D2 includes the first electrode 210, the second electrode 230 facing the first electrode 210, and the organic light emitting layer 220 therebetween. The organic light emitting layer 220 includes a first emitting part 310 including a first EML 320, a first intermediate functional layer 330, a first EBL 315 and a first HBL 317 and a second emitting part 340 including a second EML 350, a second intermediate functional layer 360, a second EBL 343 and a second HBL 345. The second emitting part 340 is positioned between the first emitting part 310 and the second electrode 230. In addition, the organic light emitting layer 220 can further include a CGL 370 between the first and second emitting parts 310 and 340. Moreover, the OLED D2 can further include a capping layer 290 for enhancing (improving) an emitting efficiency.

The organic light emitting display device can include a red pixel region, a green pixel region and a blue pixel region, and the OLED D2 is positioned in the red pixel region.

The first electrode 210 can be anode, and the second electrode 230 can be a cathode. The first electrode 210 is a reflective electrode, and the second electrode 230 is a transparent electrode (or a semi-transparent electrode). For example, the first electrode 210 can have a structure of ITO/Ag/ITO, and the second electrode 230 can be formed of MgAg or Al. Namely, the first electrode 210 can have a first transmittance, and the second electrode 230 can have a second transmittance greater than the first transmittance.

Alternatively, the first electrode 210 can be a transparent electrode, and the second electrode 230 can be a reflective electrode.

In the first emitting part 310, the first EBL 315 is positioned under the first EML 320, and the first HBL 317 is positioned over the first EML 320. Namely, the first EBL 315 is positioned between the first electrode 210 and the first EML 320, and the first HBL 317 is positioned between the first EML 320 and the second emitting part 340. The first intermediate functional layer 330 is positioned between the first EML 320 and the first HBL 317.

In the first emitting part 310, one surface (side) of the first EML 320 contacts the first EBL 315, and the other surface of the first EML 320 contacts the first intermediate functional layer 330 with being spaced apart from the first HBL 317. One surface and the other surface of the first intermediate functional layer 330 respectively contact the first EML 320 and the first HBL 317. Namely, the first EML 320, the first intermediate functional layer 330, the first HBL 317 is sequentially stacked on the first EBL 315.

The first EML 320 includes a first compound 322, a second compound 324 and a third compound 326. The first compound 322 acts as a host, the second compound 324 acts as an auxiliary host (auxiliary dopant), and the third compound 326 acts as a dopant (emitter). The second compound 324 is a delayed fluorescent compound, and the third compound 326 is a fluorescent compound.

The first intermediate functional layer 330 includes a first compound 332 and a second compound 334.

Each of the first compound 322 in the first EML 320 and the first compound 332 in the first intermediate functional layer 330 is represented by Formula 1.

The first compound 322 in the first EML 320 and the first compound 332 in the first intermediate functional layer 330 have the same chemical structure and can be same or different. For example, each of the first compound 322 in the first EML 320 and the first compound 332 in the first intermediate functional layer 330 can be one of the compounds in Formula 2.

Each of the second compound 324 in the first EML 320 and the second compound 334 in the first intermediate functional layer 330 is represented by Formula 3-1, and the second compound 324 in the first EML 320 and the second compound 334 in the first intermediate functional layer 330 are different. The second compound 324 in the first EML 320 can be represented by Formula 3a, and the second compound 334 in the first intermediate functional layer 330 can be represented by Formula 3b.

The second compound 334 in the first intermediate functional layer 330 has a higher LUMO energy level than the second compound 324 in the first EML 320.

For example, the second compound 324 in the first EML 320 is one of the compounds in Formula 4, and the second compound 334 in the first intermediate functional layer 330 is another one of the compounds in Formula 4.

The third compound 326 in the first EML 320 is represented by Formula 5 and can be one of the compounds in Formula 6.

In the first EML 320, each of a first weight % of the first compound 322 and a second weight % of the second compound 324 is greater than a third weight % of the third compound 326. The second weight % of the second compound 324 can be same as or different from the first weight % of the first compound 322. The first EML 320 consists of the first to third compounds 322, 324 and 326, and a summation of the first weight % of the first compound 322, the second weight % of the second compound 324 and the third weight % of the third compound 326 in the first EML 320 is 100 wt.%.

In the first intermediate functional layer 330, a fourth weight % of the first compound 332 is greater than a fifth weight % of the second compound 334. The first intermediate functional layer 330 consists of the first and second compounds 332 and 334, and a summation of the fourth weight % of the first compound 332 and the fifth weight % of the second compound 334 in the first intermediate functional layer 330 is 100 wt%.

The second weight % of the second compound 324 in the first EML 320 is greater than the fifth weight % of the second compound 334 in the first intermediate functional layer 330. For example, the second weight % of the second compound 324 in the first EML 320 can be 40 wt% or more and 60 wt% or less, and the fifth weight % of the second compound 334 in the first intermediate functional layer 330 can be 1 wt% or more and 10 wt% or less.

The first EML 320 has a first thickness t1, and the first intermediate functional layer 330 has a second thickness t2 being smaller than the first thickness t1. The second thickness t2 can be 40% or less of the first thickness t1. For example, the second thickness t2 can be 10 Å or more and 100 Å or less.

The first EML 320 is a layer for emitting light, while the first intermediate functional layer 330 is a layer for transporting an electron into the first EML 320 and preventing an exciton transfer from the first EML 320 and the first HBL 317.

For example, the first EBL 315 can include the compound in Formula 7, and the thickness of the first EBL 315 can be equal to or smaller than the second thickness t2 of the first intermediate functional layer 330.

For example, the first HBL 317 can include the compound in Formula 8, and the thickness of the first HBL 317 can be equal to or smaller than the second thickness t2 of the first intermediate functional layer 330.

In addition, the first emitting part 310 can further include at least one of an HIL 311 under the first EBL 315, a first HTL 313 between the first EBL 315 and the HIL 311 and a first ETL 319 on the first HBL 317.

In the second emitting part 340, the second EBL 343 is positioned under the second EML 350, and the second HBL 345 is positioned over the second EML 350. Namely, the second EBL 343 is positioned between the first emitting part 310 and the second EML 350, and the second HBL 345 is positioned between the second EML 350 and the second electrode 230. The second intermediate functional layer 360 is positioned between the second EML 350 and the second HBL 345.

In the second emitting part 340, one surface (side) of the second EML 350 contacts the second EBL 343, and the other surface of the second EML 350 contacts the second intermediate functional layer 360 with being spaced apart from the second HBL 345. One surface and the other surface of the second intermediate functional layer 360 respectively contact the second EML 350 and the second HBL 345. Namely, the second EML 350, the second intermediate functional layer 360, the second HBL 345 is sequentially stacked on the second EBL 343.

The second EML 350 includes a first compound 352, a second compound 354 and a third compound 356. The first compound 352 acts as a host, the second compound 354 acts as an auxiliary host (auxiliary dopant), and the third compound 356 acts as a dopant (emitter). The second compound 354 is a delayed fluorescent compound, and the third compound 356 is a fluorescent compound.

The second intermediate functional layer 360 includes a first compound 362 and a second compound 364.

Each of the first compound 352 in the second EML 350 and the first compound 362 in the second intermediate functional layer 360 is represented by Formula 1.

The first compound 352 in the second EML 350 and the first compound 362 in the second intermediate functional layer 360 have the same chemical structure and can be same or different. For example, each of the first compound 352 in the second EML 350 and the first compound 362 in the second intermediate functional layer 360 can be one of the compounds in Formula 2.

The first compound 322 in the first EML 320, the first compound 332 in the first intermediate functional layer 330, the first compound 352 in the second EML 350 and the first compound 362 in the second intermediate functional layer 360 can be same or different.

Each of the second compound 354 in the second EML 350 and the second compound 364 in the second intermediate functional layer 360 is represented by Formula 3-1, and the second compound 354 in the second EML 350 and the second compound 364 in the second intermediate functional layer 360 are different. The second compound 354 in the second EML 350 can be represented by Formula 3a, and the second compound 364 in the second intermediate functional layer 360 can be represented by Formula 3b.

The second compound 364 in the second intermediate functional layer 360 has a higher LUMO energy level than the second compound 354 in the second EML 350.

For example, the second compound 354 in the second EML 350 is one of the compounds in Formula 4, and the second compound 364 in the second intermediate functional layer 360 is another one of the compounds in Formula 4.

The second compound 324 in the first EML 320 and the second compound 354 in the second EML 350 can be same or different, and the second compound 334 in the first intermediate functional layer 330 and the second compound 364 in the second intermediate functional layer 360 can be same or different.

The third compound 356 in the second EML 350 is represented by Formula 5 and can be one of the compounds in Formula 6.

In the second EML 350, each of a first weight % of the first compound 352 and a second weight % of the second compound 354 is greater than a third weight % of the third compound 356. The second weight % of the second compound 354 can be same as or different from the first weight % of the first compound 352. The second EML 350 consists of the first to third compounds 352, 354 and 356, and a summation of the first weight % of the first compound 352, the second weight % of the second compound 354 and the third weight % of the third compound 356 in the second EML 350 is 100 wt.%.

In the second intermediate functional layer 360, a fourth weight % of the first compound 362 is greater than a fifth weight % of the second compound 364. The second intermediate functional layer 360 consists of the first and second compounds 362 and 364, and a summation of the fourth weight % of the first compound 362 and the fifth weight % of the second compound 364 in the second intermediate functional layer 360 is 100 wt%.

The second weight % of the second compound 354 in the second EML 350 is greater than the fifth weight % of the second compound 364 in the second intermediate functional layer 360. For example, the second weight % of the second compound 354 in the second EML 350 can be 40 wt% or more and 60 wt% or less, and the fifth weight % of the second compound 364 in the second intermediate functional layer 360 can be 1 wt% or more and 10 wt% or less.

The second EML 350 has a first thickness t1, and the second intermediate functional layer 360 has a second thickness t2 being smaller than the first thickness t1. The second thickness t2 can be 40% or less of the first thickness t1. For example, the second thickness t2 can be 10 Å or more and 100 Å or less.

The second EML 350 is a layer for emitting light, while the second intermediate functional layer 360 is a layer for transporting an electron into the second EML 350 and preventing an exciton transfer from the second EML 350 and the second HBL 345.

For example, the second EBL 343 can include the compound in Formula 7, and the thickness of the second EBL 343 can be equal to or smaller than the second thickness t2 of the second intermediate functional layer 360.

For example, the second HBL 345 can include the compound in Formula 8, and the thickness of the second HBL 345 can be equal to or smaller than the second thickness t2 of the second intermediate functional layer 360.

In addition, the second emitting part 340 can further include at least one of a second HTL 341 under the second EBL 343, an EIL 349 over the second HBL 345 and a second ETL 347 between the second HBL 345 and the EIL 349.

The CGL 370 is positioned between the first and second emitting parts 310 and 340, and the first and second emitting parts 310 and 340 are connected through the CGL 370. The first emitting part 310, the CGL 370 and the second emitting part 340 are sequentially stacked on the first electrode 210. Namely, the first emitting part 310 is positioned between the first electrode 210 and the CGL 370, and the second emitting part 340 is positioned between the second electrode 230 and the CGL 370.

The CGL 370 can be a P-N junction type CGL of an N-type CGL 372 and a P-type CGL 374. The N-type CGL 372 is positioned between the first ETL 319 and the second HTL 341, and the P-type CGL 374 is positioned between the N-type CGL 372 and the second HTL 341. The N-type CGL 372 provides an electron into the first EML 320 of the first emitting part 310, and the P-type CGL 374 provides a hole into the second EML 350 of the second emitting part 340.

The N-type CGL 372 can include a host, which can be the material of the ETLs 319 and 347, and a dopant being Li. For example, the dopant, i.e., Li, can have a weight % of 0.5 in the N-type CGL 372. The P-type CGL 374 can include the material of the HIL 311.

Each of the N-type CGL 372 and the P-type CGL 374 can have a thickness of 5 to 20 nm. In addition, the thickness of the N-type CGL 372 can be greater than the thickness of the P-type CGL 374.

The capping layer 290 is positioned on the second electrode 230. For example, the capping layer 290 can include one of the compounds in Formula 9 and can have a thickness of 50 to 200 nm.

In the OLED D2 of the present disclosure, the first EML 320 includes the second compound 324 having high quantum efficiency and the third compound 326 having narrow FWHM, and the second EML 350 includes the second compound 354 having high quantum efficiency and the third compound 356 having narrow FWHM. As a result, the OLED D2 provides hyper-fluorescence.

In addition, the first intermediate functional layer 330, which includes the second compound 334 having the same core as the second compound 324 in the first EML 320 and a higher LUMO energy level than the second compound 324 in the first EML 320, is disposed between the first EML 320 and the first HBL 317, and the second intermediate functional layer 360, which includes the second compound 364 having the same core as the second compound 354 in the second EML 350 and a higher LUMO energy level than the second compound 354 in the second EML 350, is disposed between the second EML 350 and the second HBL 345. As a result, the driving voltage and the FWHM of the OLED D2 are reduced, and the emitting efficiency (luminance) of the OLED D2 is improved.

Namely, the charge balance in the first and second EMLs 320 and 350 is improved by the first and second intermediate functional layer 330 and 360, and the exciton quenching problem resulting from the exciton transfer from the first EML 320 into the first HBL 317 and from the second EML 350 into second HBL 345 is prevented. As a result, the emitting property of the OLED D2 is improved.

Moreover, since an exciton generation zone, i.e., a recombination zone of the hole and electron, which is presented at an interface between the first EML 320 and the first HBL 317 and between the second EML 350 and the second HBL 345 in the related art OLED, is shifted toward the first and second EBLs 315 and 343, the emitting property of the OLED D2 is further improved.

Furthermore, the second compound 324 as a delayed fluorescent compound in the first EML 320 and the second compound 334 as a delayed fluorescent compound in the first intermediate functional layer 330 have the same core and similar property, and the second compound 354 as a delayed fluorescent compound in the second EML 350 and the second compound 364 as a delayed fluorescent compound in the second intermediate functional layer 360 have the same core and similar property. As a result, an interface property between the first EML 320 and the first intermediate functional layer 330 and between the second EML 350 and the second intermediate functional layer 360 is improved so that the emitting property of the OLED D2 is further improved.

FIG. 6 is a schematic cross-sectional view of an OLED according to a fourth embodiment of the present disclosure.

As shown in FIG. 6, the OLED D3 includes the first electrode 210, the second electrode 230 facing the first electrode 210, and the organic light emitting layer 220 therebetween. The organic light emitting layer 220 includes a first emitting part 410 including a first EML 420 and a second emitting part 440 including a second EML 450, an intermediate functional layer 460, an EBL 443 and an HBL 445. The second emitting part 440 is positioned between the first emitting part 410 and the second electrode 230. In addition, the organic light emitting layer 220 can further include a CGL 470 between the first and second emitting parts 410 and 440. Moreover, the OLED D3 can further include a capping layer 290 for enhancing (improving) an emitting efficiency.

The organic light emitting display device can include a red pixel region, a green pixel region and a blue pixel region, and the OLED D3 is positioned in the red pixel region.

The first electrode 210 can be anode, and the second electrode 230 can be a cathode. The first electrode 210 is a reflective electrode, and the second electrode 230 is a transparent electrode (or a semi-transparent electrode). For example, the first electrode 210 can have a structure of ITO/Ag/ITO, and the second electrode 230 can be formed of MgAg or Al. Namely, the first electrode 210 can have a first transmittance, and the second electrode 230 can have a second transmittance greater than the first transmittance.

Alternatively, the first electrode 210 can be a transparent electrode, and the second electrode 230 can be a reflective electrode.

The first EML 410 includes a fourth compound 422 and a fifth compound 424. The fourth compound 422 is a host, and the fifth compound 424 is a phosphorescent dopant (emitter).

The fourth compound 422 can be the compound in Formula 12.

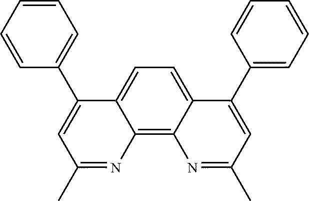 [SMILES: Cc1cc(-c2ccccc2)c2ccc3c(-c4ccccc4)cc(C)nc3c2n1]

The fifth compound 424 can be the compound in Formula 13.

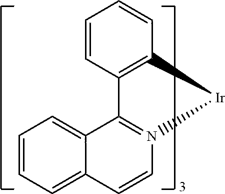

In the first EML 420, a weight % of the fourth compound 422 is greater than that of the fifth compound 424. For example, in the first EML 420, the fifth compound 424 can have a weight % of 0.1 to 10.

The first emitting part 410 further includes a first HTL 413 under the first EML 420 and a first ETL 419 on the first EML 420. Namely, the first HTL 413 is positioned between the first EML 420 and the first electrode 210, and the first ETL 419 is positioned between the first EML 420 and the second emitting part 440.

One surface and the other surface of the first EML 420 respectively contact the first HTL 413 and the first ETL 419. Namely, an EBL, an HBL and an intermediate functional layer are not presented in the first emitting part 410 including the first EML 420 being a phosphorescent emitting layer.

For example, the first HTL 413 can include one of the compounds in Formula 9, and the first ETL 519 can include one of the compounds in Formula 11.

In addition, the first emitting part 410 can further include an HIL 411 under the first HTL 413. Namely, the HIL 411 is positioned between the first electrode 210 and the first HTL 413.

In the second emitting part 440, the EBL 443 is positioned under the second EML 450, and the HBL 445 is positioned over the second EML 450. Namely, the EBL 443 is positioned between the first emitting part 410 and the second EML 450, and the HBL 445 is positioned between the second EML 450 and the second electrode 230. The intermediate functional layer 460 is positioned between the second EML 450 and the HBL 445.

In the second emitting part 440, one surface (side) of the second EML 450 contacts the EBL 443, and the other surface of the second EML 450 contacts the intermediate functional layer 460 with being spaced apart from the HBL 445. One surface and the other surface of the intermediate functional layer 460 respectively contact the second EML 450 and the HBL 445. Namely, the second EML 450, the intermediate functional layer 460, the HBL 445 is sequentially stacked on the EBL 443.

In the first emitting part 410 including the first EML 420 as a phosphorescent emitting layer, an EBL, an intermediated functional layer and an HBL are not presented so that the first EML 420 contacts the first HTL 413 and the first ETL 419. On the other hand, in the second emitting part 440 including the second EML 450 as a fluorescent emitting layer, the second EML 450 contacts the EBL 443 and the intermediated functional layer 460.

The second EML 450 includes a first compound 452, a second compound 454 and a third compound 456. The first compound 452 acts as a host, the second compound 454 acts as an auxiliary host (auxiliary dopant), and the third compound 456 acts as a dopant (emitter). The second compound 454 is a delayed fluorescent compound, and the third compound 456 is a fluorescent compound.

A difference between a maximum emission wavelength of the first EML 420 and a maximum emission wavelength of the second EML 450 can be 5 nm or less. For example, a difference between a maximum emission wavelength of the fifth compound 424 in the first EML 420 and a maximum emission wavelength of the third compound 456 in the second EML 450 can be 5 nm or less.

The intermediate functional layer 460 includes a first compound 462 and a second compound 464.

Each of the first compound 452 in the second EML 450 and the first compound 462 in the intermediate functional layer 460 is represented by Formula 1.

The first compound 452 in the second EML 450 and the first compound 462 in the intermediate functional layer 460 have the same chemical structure and can be same or different. For example, each of the first compound 452 in the second EML 450 and the first compound 462 in the intermediate functional layer 460 can be one of the compounds in Formula 2.

Each of the second compound 454 in the second EML 450 and the second compound 464 in the intermediate functional layer 460 is represented by Formula 3-1, and the second compound 454 in the second EML 450 and the second compound 464 in the intermediate functional layer 460 are different. The second compound 454 in the second EML 450 can be represented by Formula 3a, and the second compound 464 in the intermediate functional layer 460 can be represented by Formula 3b.

The second compound 464 in the intermediate functional layer 460 has a higher LUMO energy level than the second compound 454 in the second EML 450.

For example, the second compound 454 in the second EML 450 is one of the compounds in Formula 4, and the second compound 464 in the intermediate functional layer 460 is another one of the compounds in Formula 4.

The third compound 456 in the second EML 450 is represented by Formula 5 and can be one of the compounds in Formula 6.

In the second EML 450, each of a first weight % of the first compound 452 and a second weight % of the second compound 454 is greater than a third weight % of the third compound 456. The second weight % of the second compound 454 can be same as or different from the first weight % of the first compound 452. The second EML 450 consists of the first to third compounds 452, 454 and 456, and a summation of the first weight % of the first compound 452, the second weight % of the second compound 454 and the third weight % of the third compound 456 in the second EML 450 is 100 wt.%.

In the intermediate functional layer 460, a fourth weight % of the first compound 462 is greater than a fifth weight % of the second compound 464. The intermediate functional layer 460 consists of the first and second compounds 462 and 464, and a summation of the fourth weight % of the first compound 462 and the fifth weight % of the second compound 464 in the intermediate functional layer 460 is 100 wt%.

The second weight % of the second compound 454 in the second EML 450 is greater than the fifth weight % of the second compound 464 in the intermediate functional layer 460. For example, the second weight % of the second compound 454 in the second EML 450 can be 40 wt% or more and 60 wt% or less, and the fifth weight % of the second compound 464 in the intermediate functional layer 460 can be 1 wt% or more and 10 wt% or less.

The second EML 450 has a first thickness t1, and the intermediate functional layer 460 has a second thickness t2 being smaller than the first thickness t1. The second thickness t2 can be 40% or less of the first thickness t1. For example, the second thickness t2 can be 10 Å or more and 100 Å or less.

The second EML 450 is a layer for emitting light, while the intermediate functional layer 460 is a layer for transporting an electron into the second EML 450 and preventing an exciton transfer from the second EML 450 and the HBL 445.

For example, the EBL 443 can include the compound in Formula 7, and the thickness of the EBL 443 can be equal to or smaller than the second thickness t2 of the intermediate functional layer 460.

For example, the HBL 445 can include the compound in Formula 8, and the thickness of the HBL 445 can be equal to or smaller than the second thickness t2 of the intermediate functional layer 460.

In addition, the second emitting part 440 can further include at least one of a second HTL 441 under the second EBL 443, an EIL 449 over the second HBL 345 and a second ETL 447 between the second HBL 445 and the EIL 449.

The CGL 470 is positioned between the first and second emitting parts 410 and 440, and the first and second emitting parts 410 and 440 are connected through the CGL 470. The first emitting part 410, the CGL 470 and the second emitting part 440 are sequentially stacked on the first electrode 210. Namely, the first emitting part 410 is positioned between the first electrode 410 and the CGL 470, and the second emitting part 440 is positioned between the second electrode 430 and the CGL 470.

The CGL 470 can be a P-N junction type CGL of an N-type CGL 472 and a P-type CGL 474. The N-type CGL 472 is positioned between the first ETL 419 and the second HTL 441, and the P-type CGL 474 is positioned between the N-type CGL 472 and the second HTL 441. The N-type CGL 472 provides an electron into the first EML 420 of the first emitting part 410, and the P-type CGL 474 provides a hole into the second EML 450 of the second emitting part 440.

The N-type CGL 472 can include a host, which can be the material of the ETLs 419 and 447, and a dopant being Li. For example, the dopant, i.e., Li, can have a weight % of 0.5 in the N-type CGL 472. The P-type CGL 474 can include the material of the HIL 411.

Each of the N-type CGL 472 and the P-type CGL 474 can have a thickness of 5 to 20 nm. In addition, the thickness of the N-type CGL 472 can be greater than the thickness of the P-type CGL 474.

The capping layer 290 is positioned on the second electrode 230. For example, the capping layer 290 can include one of the compounds in Formula 9 and can have a thickness of 50 to 200 nm.

In the OLED D3 of the present disclosure, the first EML 420 includes the fifth compound 242 being a phosphorescent dopant, and the second EML 450 includes the second compound 454 having high quantum efficiency and the third compound 456 having narrow FWHM. As a result, the OLED D3 provides high emitting efficiency, high color purity and long lifespan.

In addition, the intermediate functional layer 460, which includes the second compound 464 having the same core as the second compound 454 in the second EML 450 and a higher LUMO energy level than the second compound 454 in the second EML 450, is disposed between the second EML 450 and the HBL 445. As a result, the driving voltage and the FWHM of the OLED D3 are reduced, and the emitting efficiency (luminance) of the OLED D3 is improved.

Namely, the charge balance in the second EML 450 is improved by the intermediate functional layer 460, and the exciton quenching problem resulting from the second EML 450 into HBL 445 is prevented. As a result, the emitting property of the OLED D3 is improved.

Moreover, since an exciton generation zone, i.e., a recombination zone of the hole and electron, which is presented at an interface between the second EML 450 and the HBL 445 in the related art OLED, is shifted toward the EBL 443, the emitting property of the OLED D3 is further improved.

Furthermore, the second compound 454 as a delayed fluorescent compound in the second EML 450 and the second compound 464 as a delayed fluorescent compound in the intermediate functional layer 460 have the same core and similar property. As a result, an interface property between the second EML 450 and the intermediate functional layer 460 is improved so that the emitting property of the OLED D3 is further improved.

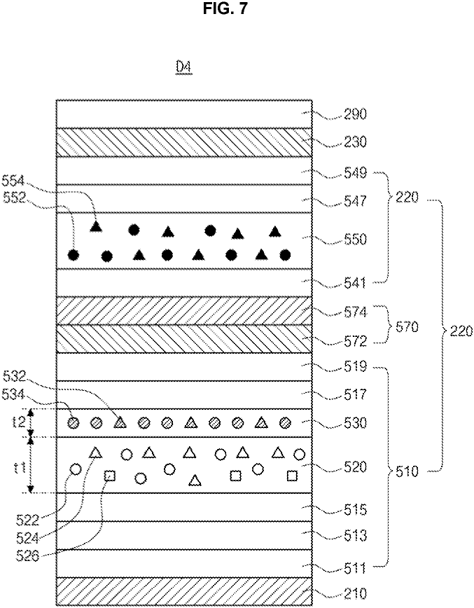

FIG. 7 is a schematic cross-sectional view of an OLED according to a fifth embodiment of the present disclosure.

As shown in FIG. 7, the OLED D4 includes the first electrode 210, the second electrode 230 facing the first electrode 210, and the organic light emitting layer 220 therebetween. The organic light emitting layer 220 includes a first emitting part 510 including a first EML 520, an intermediate functional layer 530, an EBL 515 and an HBL 517 and a second emitting part 540 including a second EML 550. The second emitting part 540 is positioned between the first emitting part 510 and the second electrode 230. In addition, the organic light emitting layer 220 can further include a CGL 570 between the first and second emitting parts 510 and 540. Moreover, the OLED D4 can further include a capping layer 290 for enhancing (improving) an emitting efficiency.

The organic light emitting display device can include a red pixel region, a green pixel region and a blue pixel region, and the OLED D4 is positioned in the red pixel region.

The first electrode 210 can be anode, and the second electrode 230 can be a cathode. The first electrode 210 is a reflective electrode, and the second electrode 230 is a transparent electrode (or a semi-transparent electrode). For example, the first electrode 210 can have a structure of ITO/Ag/ITO, and the second electrode 230 can be formed of MgAg or Al. Namely, the first electrode 210 can have a first transmittance, and the second electrode 230 can have a second transmittance greater than the first transmittance.

In the first emitting part 510, the EBL 515 is positioned under the first EML 520, and the HBL 517 is positioned over the first EML 520. Namely, the EBL 515 is positioned between the first electrode 210 and the first EML 520, and the HBL 517 is positioned between the first EML 520 and the second emitting part 540. The intermediate functional layer 530 is positioned between the first EML 520 and the HBL 517.

In the first emitting part 510, one surface (side) of the first EML 520 contacts the EBL 515, and the other surface of the first EML 520 contacts the intermediate functional layer 530 with being spaced apart from the HBL 517. One surface and the other surface of the intermediate functional layer 530 respectively contact the first EML 520 and the HBL 517. Namely, the first EML 520, the intermediate functional layer 530, the HBL 517 is sequentially stacked on the EBL 515.

The first EML 520 includes a first compound 522, a second compound 524 and a third compound 526. The first compound 522 acts as a host, the second compound 524 acts as an auxiliary host (auxiliary dopant), and the third compound 526 acts as a dopant (emitter). The second compound 524 is a delayed fluorescent compound, and the third compound 526 is a fluorescent compound.

The intermediate functional layer 530 includes a first compound 532 and a second compound 534.

Each of the first compound 522 in the first EML 520 and the first compound 532 in the intermediate functional layer 530 is represented by Formula 1.

The first compound 522 in the first EML 520 and the first compound 532 in the intermediate functional layer 530 have the same chemical structure and can be same or different. For example, each of the first compound 522 in the first EML 520 and the first compound 532 in the intermediate functional layer 530 can be one of the compounds in Formula 2.

Each of the second compound 524 in the first EML 520 and the second compound 534 in the intermediate functional layer 530 is represented by Formula 3-1, and the second compound 524 in the first EML 520 and the second compound 534 in the intermediate functional layer 530 are different. The second compound 524 in the first EML 520 can be represented by Formula 3a, and the second compound 534 in the intermediate functional layer 530 can be represented by Formula 3b.

The second compound 534 in the intermediate functional layer 530 has a higher LUMO energy level than the second compound 524 in the first EML 520.

For example, the second compound 524 in the first EML 520 is one of the compounds in Formula 4, and the second compound 534 in the intermediate functional layer 530 is another one of the compounds in Formula 4.

The third compound 526 in the first EML 520 is represented by Formula 5 and can be one of the compounds in Formula 6.

In the first EML 520, each of a first weight % of the first compound 522 and a second weight % of the second compound 524 is greater than a third weight % of the third compound 526. The second weight % of the second compound 524 can be same as or different from the first weight % of the first compound 522. The first EML 520 consists of the first to third compounds 522, 524 and 526, and a summation of the first weight % of the first compound 522, the second weight % of the second compound 524 and the third weight % of the third compound 526 in the first EML 320 is 100 wt.%.

In the intermediate functional layer 530, a fourth weight % of the first compound 532 is greater than a fifth weight % of the second compound 534. The intermediate functional layer 530 consists of the first and second compounds 532 and 534, and a summation of the fourth weight % of the first compound 532 and the fifth weight % of the second compound 534 in the intermediate functional layer 530 is 100 wt%.

The second weight % of the second compound 524 in the first EML 520 is greater than the fifth weight % of the second compound 534 in the intermediate functional layer 530. For example, the second weight % of the second compound 524 in the first EML 520 can be 40 wt% or more and 60 wt% or less, and the fifth weight % of the second compound 534 in the intermediate functional layer 530 can be 1 wt% or more and 10 wt% or less.

The first EML 520 has a first thickness t1, and the intermediate functional layer 530 has a second thickness t2 being smaller than the first thickness t1. The second thickness t2 can be 40% or less of the first thickness t1. For example, the second thickness t2 can be 10 Å or more and 100 Å or less.

The first EML 520 is a layer for emitting light, while the intermediate functional layer 530 is a layer for transporting an electron into the first EML 520 and preventing an exciton transfer from the first EML 520 and the HBL 317.

For example, the EBL 515 can include the compound in Formula 7, and the thickness of the EBL 515 can be equal to or smaller than the second thickness t2 of the intermediate functional layer 530.

For example, the HBL 517 can include the compound in Formula 8, and the thickness of the HBL 517 can be equal to or smaller than the second thickness t2 of the intermediate functional layer 530.

In addition, the first emitting part 510 can further include at least one of an HIL 511 under the EBL 515, a first HTL 513 between the EBL 515 and the HIL 511 and a first ETL 519 on the HBL 517.

The second EML 550 includes a fourth compound 552 and a fifth compound 554. The fourth compound 552 is a host, and the fifth compound 554 is a phosphorescent dopant (emitter).

The fourth compound 552 can be the compound in Formula 12, and the fifth compound 554 can be the compound in Formula 13.

The second emitting part 540 further includes a second HTL 541 under the second EML 550 and a second ETL 547 on the second EML 550. Namely, the second HTL 541 is positioned between the second EML 550 and the first emitting part 510, and the first ETL 547 is positioned between the second EML 550 and the second electrode 230.

One surface and the other surface of the second EML 550 respectively contact the second HTL 413 and the second ETL 419. Namely, an EBL, an HBL and an intermediate functional layer are not presented in the second emitting part 540 including the second EML 550 being a phosphorescent emitting layer.

For example, the second HTL 541 can include one of the compounds in Formula 9, and the second ETL 547 can include one of the compounds in Formula 11.

In addition, the second emitting part 540 can further include an EIL 549 on the second ETL 547. Namely, the EIL 549 is positioned between the second electrode 230 and the second ETL 547.

In the first emitting part 510 including the first EML 520 as a fluorescent emitting layer, the first EML 520 contacts the EBL 515 and the intermediated functional layer 530. On the other hand, in the second emitting part 540 including the second EML 550 as a phosphorescent emitting layer, since an EBL, an intermediated functional layer and an HBL are nor presented, the second EML 550 contacts the second HTL 541 and the second ETL 547.

The CGL 570 is positioned between the first and second emitting parts 510 and 540, and the first and second emitting parts 510 and 540 are connected through the CGL 570. The first emitting part 510, the CGL 570 and the second emitting part 540 are sequentially stacked on the first electrode 210. Namely, the first emitting part 510 is positioned between the first electrode 510 and the CGL 570, and the second emitting part 540 is positioned between the second electrode 530 and the CGL 570.

The CGL 570 can be a P-N junction type CGL of an N-type CGL 572 and a P-type CGL 574. The N-type CGL 572 is positioned between the first ETL 519 and the second HTL 541, and the P-type CGL 574 is positioned between the N-type CGL 572 and the second HTL 541. The N-type CGL 572 provides an electron into the first EML 520 of the first emitting part 510, and the P-type CGL 574 provides a hole into the second EML 550 of the second emitting part 540.

The N-type CGL 572 can include a host, which can be the material of the ETLs 519 and 547, and a dopant being Li. For example, the dopant, i.e., Li, can have a weight % of 0.5 in the N-type CGL 572. The P-type CGL 574 can include the material of the HIL 511.

Each of the N-type CGL 572 and the P-type CGL 574 can have a thickness of 5 to 20 nm. In addition, the thickness of the N-type CGL 572 can be greater than the thickness of the P-type CGL 574.

The capping layer 290 is positioned on the second electrode 230. For example, the capping layer 290 can include one of the compounds in Formula 9 and can have a thickness of 50 to 200 nm.

In the OLED D4 of the present disclosure, a full width at half maximum (FWHM) of the second EML 550, which is closer to the second electrode 230 being a transparent electrode, is smaller (narrower) than an FWHM of the first EML 520, which is closer to the first electrode 210 being a reflective electrode. In addition, an emitting efficiency (quantum efficiency) of the second EML 550, which is closer to the second electrode 230 being a transparent electrode, is greater than an emitting efficiency of the first EML 520, which is closer to the first electrode 210 being a reflective electrode.

Namely, in the OLED D4, the FWHM of the second EML 550, which includes the fourth compound 552 in Formula 12 and the fifth compound 554 in Formula 13, is smaller than that of the first EML 520, which includes the first compound 522 in Formula 1, the second compound 524 in Formula 3-1 and the third compound 526 in Formula 5, and the emitting efficiency of the second EML 550, which includes the fourth compound 552 in Formula 12 and the fifth compound 554 in Formula 13, is greater than that of the first EML 520, which includes the first compound 522 in Formula 1, the second compound 524 in Formula 3-1 and the third compound 526 in Formula 5.

Since the second EML 550 and the first EML 520 are respectively disposed to be closer to the second electrode 230 being the transparent electrode and the first electrode 210 being the reflective electrode, the cavity effect in the OLED D4 is enhanced so that the emitting efficiency and the lifespan of the OLED D4 are improved.

In addition, the intermediate functional layer 530, which includes the second compound 534 having the same core as the second compound 524 in the first EML 520 and a higher LUMO energy level than the second compound 524 in the first EML 520, is disposed between the first EML 520 and the HBL 517. As a result, the driving voltage and the FWHM of the OLED D4 are reduced, and the emitting efficiency (luminance) of the OLED D4 is improved.

Namely, the charge balance in the first EML 520 is improved by the intermediate functional layer 530, and the exciton quenching problem resulting from the first EML 530 into HBL 517 is prevented. As a result, the emitting property of the OLED D4 is improved.

Moreover, since an exciton generation zone, i.e., a recombination zone of the hole and electron, which is presented at an interface between the first EML 520 and the HBL 517 in the related art OLED, is shifted toward the EBL 515, the emitting property of the OLED D4 is further improved.

Furthermore, the second compound 524 as a delayed fluorescent compound in the first EML 520 and the second compound 534 as a delayed fluorescent compound in the intermediate functional layer 530 have the same core and similar property. As a result, an interface property between the first EML 520 and the intermediate functional layer 530 is improved so that the emitting property of the OLED D4 is further improved.

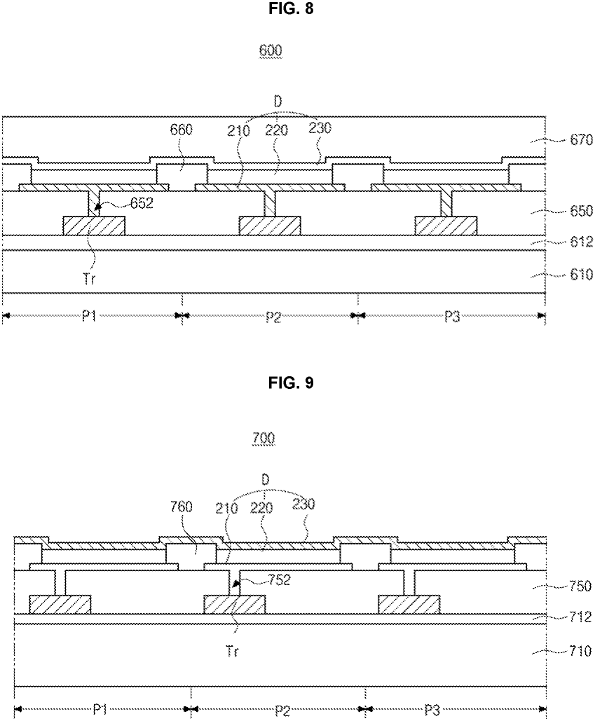

FIG. 8 is a schematic cross-sectional view of an organic light emitting display device according to a sixth embodiment of the present disclosure.

As shown in FIG. 8, the organic light emitting display device 600 includes a substrate 610, wherein first to third pixel regions P1, P2 and P3 are defined, a TFT Tr over the substrate 610 and an OLED D. The OLED D is disposed over the TFT Tr and is connected to the TFT Tr.

For example, the first to third pixel regions P1, P2 and P3 can be a green pixel region, a red pixel region and a blue pixel region, respectively. The first to third pixel regions P1, P2 and P3 constitute a pixel unit. Alternatively, the pixel unit can further include a white pixel region.

The substrate 610 can be a glass substrate or a flexible substrate.

A buffer layer 612 is formed on the substrate 610, and the TFT Tr is formed on the buffer layer 612. The buffer layer 612 can be omitted.

The TFT Tr is positioned on the buffer layer 612. The TFT Tr includes a semiconductor layer, a gate electrode, a source electrode and a drain electrode and acts as a driving element. Namely, the TFT Tr can be the driving TFT Td (of FIG. 1).

A planarization layer (or passivation layer) 650 is formed on the TFT Tr. The planarization layer 650 has a flat top surface and includes a drain contact hole 652 exposing the drain electrode of the TFT Tr.

The OLED D is disposed on the planarization layer 650 and includes a first electrode 210, an organic light emitting layer 220 and a second electrode 230. The first electrode 210 is connected to the drain electrode of the TFT Tr, and the organic light emitting layer 220 and the second electrode 230 are sequentially stacked on the first electrode 210. The OLED D is disposed in each of the first to third pixel regions P1 to P3 and emits different color light in the first to third pixel regions P1 to P3. For example, the OLED D in the first pixel region P1 can emit the red light, the OLED D in the second pixel region P2 can emit the green light, and the OLED D in the third pixel region P3 can emit the blue light.

The first electrode 210 is formed to be separated in the first to third pixel regions P1 to P3, and the second electrode 230 is formed as one-body to cover the first to third pixel regions P1 to P3.

The first electrode 210 is one of an anode and a cathode, and the second electrode 230 is the other one of the anode and the cathode. In addition, the first electrode 210 is a reflective electrode, and the second electrode 230 is a transparent electrode (or a semi-transparent electrode). Namely, the light from the OLED D passes through the second electrode 230 to display an image. (i.e., a top-emission type organic light emitting display device)

For example, the first electrode 210 can be an anode and can include a transparent conductive oxide material layer, which can be formed of a conductive material, e.g., a transparent conductive oxide (TCO), having a relatively high work function, and a reflection layer. Namely, the first electrode 210 can be a reflective electrode.

The second electrode 230 can a cathode and can be formed of a conductive material having a relatively low work function. The second electrode 230 can have a thin profile to be transparent (or semi-transparent).

The organic light emitting layer 220 can have a structure explained with FIGS. 3 and 5 to 7.

Referring to FIG. 3, the organic light emitting layer 220 includes an EML 260, which includes a first compound 262 represented by Formula 1, a second compound 264 represented by Formula 3 and a third compound 266 represented by Formula 5, an HBL 252 at a side of the EML 260 and an intermediate functional layer 270, which includes a second compound 274 represented by Formula 3 and having a higher LUMO energy level than the second compound 264 in the EML 260, positioned between the EML 260 and the HBL 252.

A difference between an LUMO energy level of the second compound 274 in the intermediate functional layer 270 and an LUMO energy level of the second compound 264 in the EML 260 can be 0.5 eV or less, and the LUMO energy level of the second compound 264 in the EML 260 can be lower than 3.0 eV.

The weight % of the second compound 264 in the EML 260 is greater than the weight % of the second compound 274 in the intermediate functional layer 270. For example, the weight % of the second compound 264 in the EML 260 can be 40 wt% or more and 60 wt% or less, and the weight % of the second compound 274 in the intermediate functional layer 270 can be 1 wt% or more and 10 wt% or less.

The EML 260 has a first thickness t1, and the intermediate functional layer 270 has a second thickness t2 being smaller than the first thickness t1. The second thickness t2 can be 40% or less of the first thickness t1. For example, the second thickness t2 can be 10 Å or more and 100 Å or less.

A first surface of the EML 260 contacts the intermediate functional layer 270 and is spaced apart from the HBL 252, and a second surface of the EML 260 contacts the EBL 246.

Referring to FIG. 5, the organic light emitting layer 220 includes a first emitting part 310 including a first EML 320, which includes a first compound 322 represented by Formula 1, a second compound 324 represented by Formula 3 and a third compound 326 represented by Formula 5, a first HBL 317 at a side of the first EML 320 and a first intermediate functional layer 330, which includes a second compound 334 represented by Formula 3 and has a higher LUMO energy level than the second compound 324 in the EML 320, positioned between the EML 320 and the HBL 317, and a second emitting part 340 including a second EML 350 , which includes a second compound 352 represented by Formula 1, a second compound 354 represented by Formula 3 and a third compound 356 represented by Formula 5, a second HBL 345 at a side of the second EML 350 and a second intermediate functional layer 360, which includes a second compound 364 represented by Formula 3 and having a higher LUMO energy level than the second compound 354 in the EML 350, positioned between the second EML 350 and the second HBL 354.

A difference between an LUMO energy level of the second compound 334 in the first intermediate functional layer 330 and an LUMO energy level of the second compound 324 in the first EML 320 can be 0.5 eV or less, and the LUMO energy level of the second compound 324 in the first EML 320 can be lower than 3.0 eV.

The weight % of the second compound 324 in the first EML 320 is greater than the weight % of the second compound 334 in the first intermediate functional layer 330. For example, the weight % of the second compound 324 in the first EML 320 can be 40 wt% or more and 60 wt% or less, and the weight % of the second compound 334 in the first intermediate functional layer 330 can be 1 wt% or more and 10 wt% or less.

The first EML 320 has a first thickness t1, and the first intermediate functional layer 330 has a second thickness t2 being smaller than the first thickness t1. The second thickness t2 can be 40% or less of the first thickness t1. For example, the second thickness t2 can be 10 Å or more and 100 Å or less.

A first surface of the first EML 320 contacts the first intermediate functional layer 330 and is spaced apart from the first HBL 317, and a second surface of the first EML 320 contacts the first EBL 315.

A difference between an LUMO energy level of the second compound 364 in the second intermediate functional layer 360 and an LUMO energy level of the second compound 354 in the second EML 350 can be 0.5 eV or less, and the LUMO energy level of the second compound 354 in the second EML 350 can be lower than 3.0 eV.

The weight % of the second compound 354 in the second EML 350 is greater than the weight % of the second compound 364 in the second intermediate functional layer 360. For example, the weight % of the second compound 354 in the second EML 350 can be 40 wt% or more and 60 wt% or less, and the weight % of the second compound 364 in the second intermediate functional layer 360 can be 1 wt% or more and 10 wt% or less.

The second EML 350 has a first thickness t1, and the second intermediate functional layer 360 has a second thickness t2 being smaller than the first thickness t1. The second thickness t2 can be 40% or less of the first thickness t1. For example, the second thickness t2 can be 10 Å or more and 100 Å or less.

A first surface of the second EML 350 contacts the second intermediate functional layer 360 and is spaced apart from the second HBL 345, and a second surface of the second EML 350 contacts the second EBL 343.

Referring to FIG. 6, the organic light emitting layer 220 includes a first emitting part 410 including a first EML 420, which includes a fourth compound 422 in Formula 12 and a fifth compound 424 in Formula 13, and a second EML 440, which includes a second EML 450, which includes a first compound 452 represented by Formula 1, a second compound 454 represented by Formula 3 and a third compound 456 represented by Formula 5, an HBL 445 at a side of the second EML 450 and an intermediate functional layer 460, which includes a second compound 464 represented by Formula 3 and having a higher LUMO energy level than the second compound 454 in the second EML 450, positioned between the second EML 450 and the HBL 445.

The first emitting part 410 further includes a first HTL 413, which is positioned at a first side of the first EML 420 and contacts the first EML 420, and a first ETL 419, which is positioned at a second side of the first EML 420 and contacts the first EML 420.

A difference between an LUMO energy level of the second compound 464 in the second intermediate functional layer 460 and an LUMO energy level of the second compound 454 in the second EML 450 can be 0.5 eV or less, and the LUMO energy level of the second compound 454 in the second EML 450 can be lower than 3.0 eV.

The weight % of the second compound 454 in the second EML 450 is greater than the weight % of the second compound 464 in the second intermediate functional layer 460. For example, the weight % of the second compound 454 in the second EML 450 can be 40 wt% or more and 60 wt% or less, and the weight % of the second compound 464 in the second intermediate functional layer 460 can be 1 wt% or more and 10 wt% or less.

The second EML 450 has a first thickness t1, and the second intermediate functional layer 460 has a second thickness t2 being smaller than the first thickness t1. The second thickness t2 can be 40% or less of the first thickness t1. For example, the second thickness t2 can be 10 Å or more and 100 Å or less.

A first surface of the second EML 450 contacts the second intermediate functional layer 460 and is spaced apart from the HBL 445, and a second surface of the second EML 450 contacts the EBL 443.

Referring to FIG. 7, the organic light emitting layer 220 includes a first emitting part 310 including a first EML 520, which includes a first compound 522 represented by Formula 1, a second compound 524 represented by Formula 3 and a third compound 526 represented by Formula 5, a HBL 517 at a side of the first EML 520 and an intermediate functional layer 530, which includes a second compound 534 represented by Formula 3 and has a higher LUMO energy level than the second compound 524 in the EML 520, positioned between the EML 520 and the HBL 517, and a second emitting part 540 including a second EML 550 , which includes a fourth compound 552 in Formula 12 and a fifth compound 524 in Formula 13.

A difference between an LUMO energy level of the second compound 534 in the first intermediate functional layer 530 and an LUMO energy level of the second compound 524 in the first EML 520 can be 0.5 eV or less, and the LUMO energy level of the second compound 524 in the first EML 520 can be lower than 3.0 eV.

The weight % of the second compound 524 in the first EML 520 is greater than the weight % of the second compound 534 in the first intermediate functional layer 530. For example, the weight % of the second compound 524 in the first EML 520 can be 40 wt% or more and 60 wt% or less, and the weight % of the second compound 534 in the first intermediate functional layer 530 can be 1 wt% or more and 10 wt% or less.

The first EML 520 has a first thickness t1, and the first intermediate functional layer 530 has a second thickness t2 being smaller than the first thickness t1. The second thickness t2 can be 40% or less of the first thickness t1. For example, the second thickness t2 can be 10 Å or more and 100 Å or less.

A first surface of the first EML 520 contacts the first intermediate functional layer 530 and is spaced apart from the HBL 517, and a second surface of the first EML 520 contacts the EBL 515.

The second emitting part 540 further includes a second HTL 541, which is positioned at a first side of the second EML 550 and contacts the second EML 550, and a second ETL 547, which is positioned at a second side of the second EML 550 and contacts the second EML 550.

The OLED D can further include the capping layer on the second electrode 230. The emitting efficiency of the OLED D can be further improved by the capping layer.

An encapsulation film (or an encapsulation layer) 670 is formed on the second electrode 230 to prevent penetration of moisture into the OLED D. The encapsulation film 670 can have a structure including an inorganic insulating layer and an organic insulating layer.

Although , the organic light emitting display device 600 can include a color filter corresponding to the red, green and blue pixel regions. For example, the color filter can be positioned on or over the OLED D or the encapsulation film 670.

In addition, the organic light emitting display device 600 can further include a cover window on or over the encapsulation film 670 or the color filter. In this instance, the substrate 610 and the cover window have a flexible property such that a flexible organic light emitting display device can be provided.

FIG. 9 is a schematic cross-sectional view of an organic light emitting display device according to a seventh embodiment of the present disclosure.

As shown in FIG. 9, the organic light emitting display device 700 includes a substrate 710, wherein first to third pixel regions P1, P2 and P3 are defined, a TFT Tr over the substrate 710 and an OLED D. The OLED D is disposed over the TFT Tr and is connected to the TFT Tr.

For example, the first to third pixel regions P1, P2 and P3 can be a red pixel region, a green pixel region and a blue pixel region, respectively. The first to third pixel regions P1, P2 and P3 constitute a pixel unit. Alternatively, the pixel unit can further include a fourth pixel region being a white pixel region.

The substrate 710 can be a glass substrate or a flexible substrate.

A buffer layer 712 is formed on the substrate 710, and the TFT Tr is formed on the buffer layer 712. The buffer layer 712 can be omitted.

The TFT Tr is positioned on the buffer layer 712. The TFT Tr includes a semiconductor layer, a gate electrode, a source electrode and a drain electrode and acts as a driving element. Namely, the TFT Tr can be the driving TFT Td (of FIG. 1).

A planarization layer (or passivation layer) 750 is formed on the TFT Tr. The planarization layer 750 has a flat top surface and includes a drain contact hole 752 exposing the drain electrode of the TFT Tr.

The OLED D is disposed on the planarization layer 750 and includes a first electrode 210, an organic light emitting layer 220 and a second electrode 230. The first electrode 210 is connected to the drain electrode of the TFT Tr, and the organic light emitting layer 220 and the second electrode 230 are sequentially stacked on the first electrode 210. The OLED D is disposed in each of the first to third pixel regions P1 to P3 and emits different color light in the first to third pixel regions P1 to P3. For example, the OLED D in the first pixel region P1 can emit the red light, the OLED D in the second pixel region P2 can emit the green light, and the OLED D in the third pixel region P3 can emit the blue light.

The first electrode 210 is formed to be separated in the first to third pixel regions P1 to P3, and the second electrode 230 is formed as one-body to cover the first to third pixel regions P1 to P3.

The first electrode 210 is one of an anode and a cathode, and the second electrode 230 is the other one of the anode and the cathode. In addition, the first electrode 210 is a transparent electrode (or a semi-transparent electrode), and the second electrode 230 is a reflective electrode. Namely, the light from the OLED D passes through the first electrode 210 to display an image on the substrate 710. (i.e., a bottom-emission type organic light emitting display device)

For example, the first electrode 210 can be an anode and can include a conductive material, e.g., a transparent conductive oxide (TCO), having a relatively high work function, and a reflection layer.

The second electrode 230 can a cathode and can be formed of a conductive material having a relatively low work function.

The organic light emitting layer 220 can have a structure explained with FIG. 3 and FIGS. 5 to 7.

An encapsulation film (or an encapsulation layer) can be formed on the second electrode 230 to prevent penetration of moisture into the OLED D. The encapsulation film can have a structure including an inorganic insulating layer and an organic insulating layer.

Although , the organic light emitting display device 700 can include a color filter corresponding to the red, green and blue pixel regions. For example, the color filter can be positioned between the OLED D and the substrate 710.

### OLED1

An anode (ITO/APC/ITO), an HIL (the compound in Formula 14-1 (8 wt% doping) and the compound in Formula 14-2, 70 nm), an HTL (the compound in Formula 14-2, 30 nm), an EBL (the compound in Formula 14-3, 10 nm), an EML, an HBL (the compound in Formula 14-4, 10 nm), an ETL (the compound in Formula 14-5, 30 nm), an EIL (LiF, 5 nm), a cathode (AgMg, 15 nm) and a capping layer (the compound in Formula 14-6, 100 nm) are sequentially deposited to form an OLED in the red pixel region.

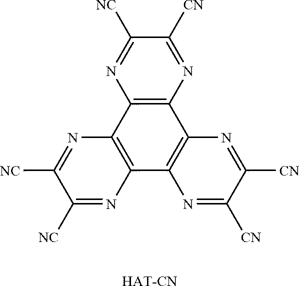

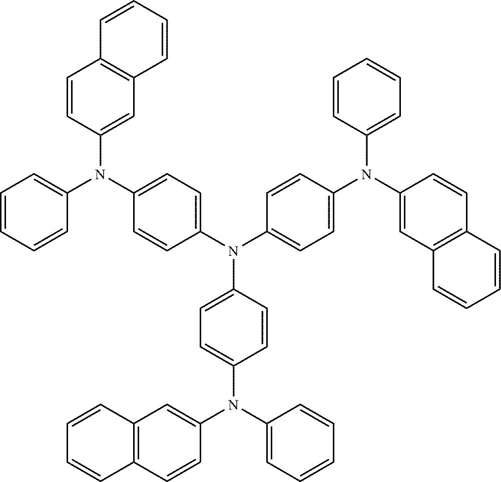 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

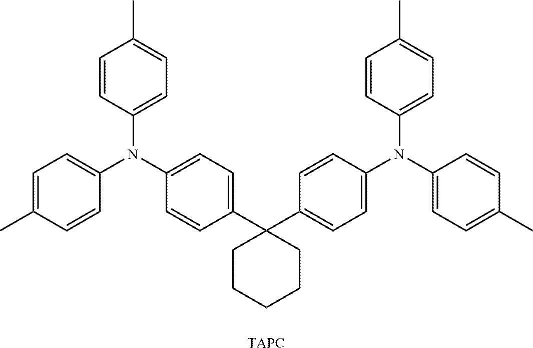

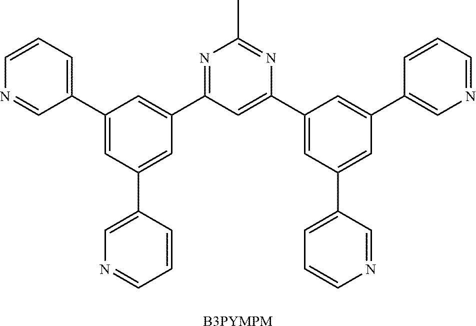 [SMILES: Cc1nc(-c2cc(-c3cccnc3)cc(-c3cccnc3)c2)cc(-c2cc(-c3cccnc3)cc(-c3cccnc3)c2)n1 ; "B3PYMPM"]

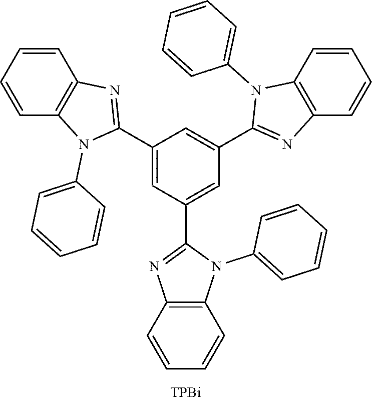

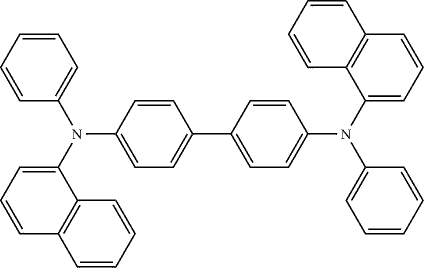 [SMILES: c1ccc(N(c2ccc(-c3ccc(N(c4ccccc4)c4cccc5ccccc45)cc3)cc2)c2cccc3ccccc23)cc1]

### 1. Comparative Examples

### Comparative Example 1 (Ref1)

The compound H-3 in Formula 2 (49.5 wt%), the compound TD-2 in Formula 4 (50 wt%) and the compound FD-1 in Formula 6 (0.5 wt%) are used to form the EML (360 Å).

### Comparative Example 2 (Ref2)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (90 wt%) and the compound TD-2 in Formula 4 (10 wt%) are used to form an intermediate functional layer (50 Å) between the EML and the HBL.

### Comparative Example 3 (Ref3)

The compound H-3 in Formula 2 (49.5 wt%), the compound TD-3 in Formula 4 (50 wt%) and the compound FD-1 in Formula 6 (0.5 wt%) are used to form the EML (360 Å), and the compound H-3 in Formula 2 (90 wt%) and the compound TD-2 in Formula 4 (10 wt%) are used to form an intermediate functional layer (50 Å) between the EML and the HBL.

### Comparative Example 4 (Ref4)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (150 Å) between the EML and the HBL.

### Comparative Example 5 (Ref5)

The compound H-3 in Formula 2 (64.5 wt%), the compound TD-2 in Formula 4 (35 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### Comparative Example 6 (Ref6)

The compound H-3 in Formula 2 (74.5 wt%), the compound TD-2 in Formula 4 (25 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### Comparative Example 7 (Ref7)

The compound H-3 in Formula 2 (89.5 wt%), the compound TD-2 in Formula 4 (10 wt%) and the compound FD-1 in Formula 6 (0.5 wt%) are used to form the EML (360 Å), and the compound H-3 in Formula 2 (50 wt%) and the compound TD-3 in Formula 4 (50 wt%) are used to form an intermediate functional layer (50 Å) between the EML and the HBL.

### Comparative Example 8 (Ref8)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (50 wt%) and the compound TD-3 in Formula 4 (50 wt%) are used to form an intermediate functional layer (50 Å) between the EML and the HBL.

### Comparative Example 9 (Ref9)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (70 wt%) and the compound TD-3 in Formula 4 (30 wt%) are used to form an intermediate functional layer (50 Å) between the EML and the HBL.

### Comparative Example 10 (Ref10)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (90 wt%) and a compound in Formula 15 (10 wt%) are used to form an intermediate functional layer (50 Å) between the EML and the HBL.

### Comparative Example 11 (Ref11)

The compound H-3 in Formula 2 (49.5 wt%), the compound TD-2 in Formula 4 (50 wt%) and the compound FD-1 in Formula 6 (0.5 wt%) are used to form the EML (100 Å), and the compound H-3 in Formula 2 (95 wt%) and the compound TD-3 in Formula 4 (5 wt%) are used to form an intermediate functional layer (360 Å) between the EML and the HBL.

### Comparative Example 12 (Ref12)

The compound in Formula 12 (98 wt%) and the compound in Formula 13 (2 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### Comparative Example 13 (Ref13)

The compound in Formula 12 (98 wt%) and the compound in Formula 13 (2 wt%) are used to form the EML (360 Å).

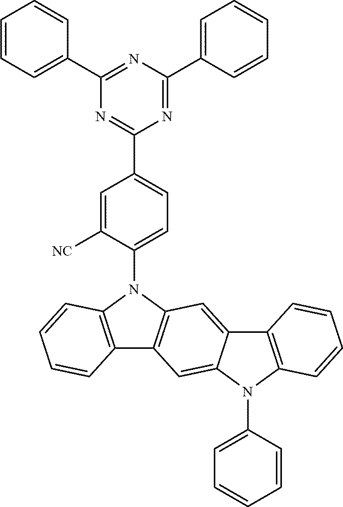 [SMILES: N#Cc1cc(-c2nc(-c3ccccc3)nc(-c3ccccc3)n2)ccc1-n1c2ccccc2c2cc3c(cc21)c1ccccc1n3-c1ccccc1]

### 2. Examples

### Example 1 (Ex1)

The compound H-3 in Formula 2 (59.5 wt%), the compound TD-2 in Formula 4 (40 wt%) and the compound FD-1 in Formula 6 (0.5 wt%) are used to form the EML (360 Å), and the compound H-3 in Formula 2 (95 wt%) and the compound TD-3 in Formula 4 (5 wt%) are used to form an intermediate functional layer (50 Å) between the EML and the HBL.

### Example 2 (Ex2)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (95 wt%) and the compound TD-3 in Formula 4 (5 wt%) are used to form an intermediate functional layer (50 Å) between the EML and the HBL.

### Example 3 (Ex3)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### Example 4 (Ex4)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (95 wt%) and the compound TD-3 in Formula 4 (5 wt%) are used to form an intermediate functional layer (70 Å) between the EML and the HBL.

### Example 5 (Ex5)

The compound H-3 in Formula 2 (59.5 wt%), the compound TD-4 in Formula 4 (40 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### Example 6 (Ex6)

The compound H-3 in Formula 2 (49.5 wt%), the compound TD-4 in Formula 4 (50 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### OLED2

An anode (ITO/APC/ITO), an HIL (the compound in Formula 14-1 (8 wt% doping) and the compound in Formula 14-2, 70 nm), a first HTL (the compound in Formula 14-2, 30 nm), an EBL (the compound in Formula 14-3, 10 nm), a first EML, an intermediate functional layer, an HBL (the compound in Formula 14-4, 10 nm), a first ETL (the compound in Formula 14-5, 30 nm), an N-CGL (the compound in Formula 14-5 (98 wt%) and Li (2 wt%), 10 nm), a P-CGL (the compound in Formula 14-1 (8 wt% doping) and the compound 14-2, 8 nm), a second HTL (the compound in Formula 14-2, 30 nm), a second EML (the compound in Formula 12 (98 wt%) and the compound in Formula 13 (2 wt%), 36 nm), a second ETL (the compound in Formula 14-5, 30 nm), an EIL (LiF, 5 nm), a cathode (AgMg, 15 nm) and a capping layer (the compound in Formula 14-6, 100 nm) are sequentially deposited to form an OLED in the red pixel region.

### 3. Examples

### Example 7 (Ex7)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (95 wt%) and the compound TD-3 in Formula 4 (5 wt%) are used to form an intermediate functional layer (50 Å) between the EML and the HBL.

### Example 8 (Ex8)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### Example 9 (Ex9)

The compound H-3 in Formula 2 (59.5 wt%), the compound TD-4 in Formula 4 (40 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### Example 10 (Ex10)

The compound H-3 in Formula 2 (49.5 wt%), the compound TD-4 in Formula 4 (50 wt%) and the compound FD-1 in Formula 6 (0.5 wt%) are used to form the EML (360 Å), and the compound H-3 in Formula 2 (90 wt%) and the compound TD-3 in Formula 4 (10 wt%) are used to form an intermediate functional layer (50 Å) between the EML and the HBL.

### Example 11 (Ex11)

The compound H-3 in Formula 2 (59.5 wt%), the compound TD-1 in Formula 4 (40 wt%) and the compound FD-1 in Formula 6 (0.5 wt%) are used to form the EML (360 Å), and the compound H-3 in Formula 2 (90 wt%) and the compound TD-4 in Formula 4 (10 wt%) are used to form an intermediate functional layer (50 Å) between the EML and the HBL.

### Example 12 (Ex12)

The compound H-3 in Formula 2 (49.5 wt%), the compound TD-1 in Formula 4 (50 wt%) and the compound FD-1 in Formula 6 (0.5 wt%) are used to form the EML (360 Å), and the compound H-3 in Formula 2 (90 wt%) and the compound TD-4 in Formula 4 (10 wt%) are used to form an intermediate functional layer (50 Å) between the EML and the HBL.

### Example 13 (Ex13)

The compound H-3 in Formula 2 (49.5 wt%), the compound TD-2 in Formula 4 (50 wt%) and the compound FD-1 in Formula 6 (0.5 wt%) are used to form the EML (360 Å), and the compound H-3 in Formula 2 (90 wt%) and the compound TD-4 in Formula 4 (10 wt%) are used to form an intermediate functional layer (50 Å) between the EML and the HBL.

The emitting properties, i.e., the driving voltage (V), the color coordinate index (CIE), the luminance (cd/A), the maximum emission wavelength (ELmax) and the FWHM, of the OLED in Comparative Examples 1 to 13 and Examples 1 to 13 are measured and listed in Tables 1 and 2.

A HOMO energy level and a LUMO energy level of the compound TD-1, the compound TD-2, the compound TD-3, the compound TD-4, the compound FD-1, the compound in Formula 15 “TD_Ref” are measured and listed in Table 3. (The HOMO energy level and the LUMO energy level are a simulation data by B3LYP/6-31 G(d))

TABLE 1

| | V | CIEx | CIEy | cd/A | ELmax (nm) | FWHM (nm) |
|---|---|---|---|---|---|---|
| Ref1 | 4.37 | 0.679 | 0.320 | 39.3 | 622 | 32 |
| Ref2 | 5.01 | 0.680 | 0.319 | 21.4 | 624 | 32 |
| Ref3 | 5.41 | 0.685 | 0.313 | 14.2 | 628 | 37 |
| Ref4 | 4.44 | 0.681 | 0.317 | 31.6 | 622 | 32 |
| Ref5 | 4.91 | 0.678 | 0.320 | 36.3 | 624 | 32 |
| Ref6 | 5.17 | 0.677 | 0.322 | 30.6 | 622 | 32 |
| Ref7 | 4.89 | 0.677 | 0.321 | 20.5 | 622 | 32 |
| Ref8 | 5.66 | 0.685 | 0.314 | 21.5 | 622 | 35 |
| Ref9 | 5.46 | 0.685 | 0.314 | 24.1 | 624 | 34 |
| Ref10 | 5.89 | 0.676 | 0.323 | 13.1 | 620 | 32 |
| Ref11 | 4.80 | 0.613 | 0.385 | 18.8 | 612 | 41 |
| Ref12 | 4.58 | 0.673 | 0.325 | 50.3 | 618 | 30 |
| Ref13 | 3.74 | 0.680 | 0.317 | 52.4 | 620 | 31 |

TABLE 2

| | V | CIEx | CIEy | cd/A | ELmax (nm) | FWHM (nm) |
|---|---|---|---|---|---|---|
| Ex1 | 3.66 | 0.676 | 0.323 | 56.7 | 618 | 30 |
| Ex2 | 3.84 | 0.680 | 0.318 | 46.2 | 620 | 31 |
| Ex3 | 3.74 | 0.684 | 0.310 | 53.6 | 624 | 31 |
| Ex4 | 4.08 | 0.680 | 0.318 | 51.7 | 622 | 30 |
| Ex5 | 4.12 | 0.676 | 0.322 | 51.4 | 621 | 29 |
| Ex6 | 4.00 | 0.676 | 0.322 | 49.4 | 618 | 29 |
| Ex7 | 7.42 | 0.673 | 0.324 | 85.7 | 618 | 29 |
| Ex8 | 7.01 | 0.679 | 0.319 | 95.3 | 620 | 30 |
| Ex9 | 7.29 | 0.675 | 0.326 | 93.2 | 622 | 30 |
| Ex10 | 7.46 | 0.682 | 0.317 | 88.1 | 622 | 28 |
| Ex11 | 7.73 | 0.680 | 0.318 | 88.4 | 622 | 30 |
| Ex12 | 7.75 | 0.675 | 0.323 | 87.7 | 620 | 30 |
| Ex13 | 7.76 | 0.677 | 0.321 | 85.9 | 620 | 30 |

TABLE 3

| | HOMO (eV) | LUMO (eV) |
|---|---|---|
| TD-1 | 5.98 | 3.79 |
| TD-2 | 5.84 | 3.69 |
| TD-3 | 5.90 | 3.50 |
| TD-4 | 5.80 | 3.60 |
| TD_Ref | 5.35 | 2.80 |
| FD-1 | 5.5 | 3.5 |

As shown in Tables 1 and 2, in comparison to the OLED of Ref1 to Ref13, the OLED of Ex1 to Ex6, which includes the EML (a fluorescent emitting layer) including a first compound represented by Formula 1, a second compound represented by Formula 3 and a third compound represented by Formula 5 and the intermediated functional layer including a compound, which has a higher LUMO energy level than the second compound in the fluorescent emitting layer, and positioned between the fluorescent emitting layer and the HBL, has advantages in the driving voltage, the emitting efficiency and the FWHM. In addition, in the OLED of Ex7 to Ex13, although the driving voltage is increased, the emitting efficiency is significantly increased.

In the OLED of Ref2, the intermediate functional layer includes the second compound being same as the second compound in the EML. In this case, the LUMO level of the second compound in the intermediate functional layer is not higher than that of the second compound in the EML. As a result, the OLED of Ref2 has higher driving voltage and lower emitting efficiency than the OLED of Ref1.

In the OLED of Ref3, the LUMO level of the second compound in the intermediate functional layer is lower than that of the second compound in the EML. As a result, the OLED of Ref3 has higher driving voltage, lower emitting efficiency and wider FWHM than the OLED of Ref1.

In the OLED of Ref4, the thickness, i.e., 150 Å, of the intermediate functional layer is over 40% of the thickness, i.e., 360 Å, of the EML. As a result, the OLED of Ref4 has higher driving voltage and lower emitting efficiency than the OLED of Ref1.

In the OLED of Ref5 and Ref6, the weight % of the second compound in the EML is too low. As a result, the OLED of Ref5 and Ref6 has higher driving voltage and lower emitting efficiency than the OLED of Ref1.

In the OLED of Ref7, the weight % of the second compound in the intermediate functional layer is greater than the weight % of the second compound in the EML. As a result, the OLED of Ref7 has higher driving voltage and lower emitting efficiency than the OLED of Ref1.

In the OLED of Ref8 and Ref9, the weight % of the second compound in the intermediate functional layer is too low. As a result, the OLED of Ref8 and Ref9 has higher driving voltage, lower emitting efficiency and wider FWHM than the OLED of Ref1.

In the OLED of Ref10, the HOMO energy level of the second compound, i.e., the compound in Formula 15, in the intermediate functional layer is higher than that of the third compound in the EML, and a difference between the LUMO energy level of the second compound, i.e., the compound in Formula 15, in the intermediate functional layer and the second compound in the EML is too large. As a result, the OLED of Ref10 has higher driving voltage and lower emitting efficiency than the OLED of Ref1.

In the OLED of Ref11, the thickness of the intermediate functional layer is greater than that of the EML. As a result, the OLED of Ref11 has higher driving voltage, lower emitting efficiency and wider FWHM than the OLED of Ref1.

In the OLED of Ref12, the intermediate functional layer including the compound TD-3 is formed with contacting a phosphorescent emitting layer. As a result, the OLED of Ref12 has higher driving voltage and lower emitting efficiency than the OLED of Ref13, which does not include an intermediate functional layer.

In the OLED of the present disclosure, the EML (a fluorescent emitting layer) includes a first compound represented by Formula 1, a second compound represented by Formula 3 and a third compound represented by Formula 5, and the intermediate functional layer, which includes a compound having a higher LUMO energy level than the second compound of the EML, is positioned between the EML and the HBL. As a result, the emitting performance of the OLED and the organic light emitting display device including the OLED is improved.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organic light emitting diode, comprising:
a first electrode;
a second electrode facing the first electrode; and
a first emitting part including a first emitting material layer between the first and second electrodes, a first hole blocking layer between the second electrode and the first emitting material layer, and a first intermediate functional layer between the first emitting material layer and the first hole blocking layer,
wherein the first emitting material layer includes a first compound, a second compound and a third compound, and the first intermediate functional layer includes a first compound and a second compound, and
wherein the second compound in the first intermediate functional layer has a core that is the same as the second compound in the first emitting material layer, and has a higher lowest unoccupied molecular orbital (LUMO) energy level than the second compound in the first emitting material layer;
wherein each of the second compound in the first emitting material layer and the second compound in the first intermediate functional layer is represented by Formula 3-1: 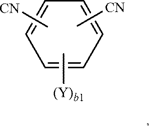
wherein b1 is an integer of 0 to 4, and Y is represented by Formula 3-2: 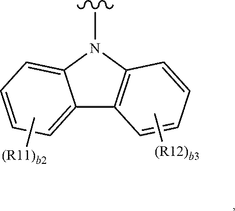
wherein each of R11 and R12 is independently selected from the group consisting of a substituted or unsubstituted C1 to C10 alkyl group, a substituted or unsubstituted C6 to C30 aryl group and a substituted or unsubstituted C5 to C30 heteroaryl group, or at least one of two adjacent R11s and two adjacent R12s is connected to each other, together with the atoms to which they are attached, to form an aromatic ring or a heteroaromatic ring, and
wherein each of b2 and b3 is independently an integer of 0 to 4.

2. The organic light emitting diode according to claim 1, wherein the first emitting material layer contacts the first intermediate functional layer, and
wherein the hole blocking layer contacts the first intermediate functional layer.

3. The organic light emitting diode according to claim 1, wherein the second compound in the first emitting material layer and the second compound in the first intermediate functional layer are different compounds.

4. The organic light emitting diode according to claim 1, wherein the second compound in the first emitting material layer is represented by Formula 3a, and the second compound in the first intermediate functional layer is represented by Formula 3b: 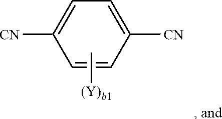 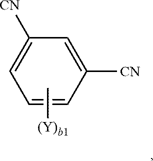
wherein Y and b1 are same as defined in Formula 3-1.

5. The organic light emitting diode according to claim 1, wherein the second compound in the first emitting material layer is one of compounds in Formula 4, and the second compound in the first intermediate functional layer is another one of the compounds in Formula 4: 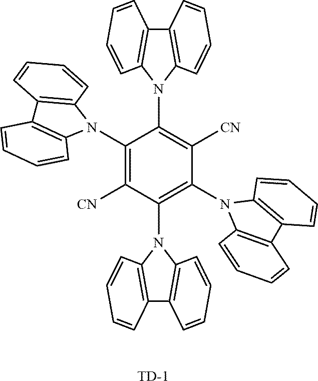 [SMILES: N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21 ; "TD-1"] 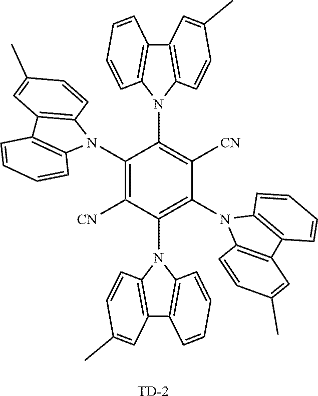 [SMILES: Cc1ccc2c(c1)c1ccccc1n2-c1c(C#N)c(-n2c3ccccc3c3cc(C)ccc32)c(-n2c3ccccc3c3cc(C)ccc32)c(C#N)c1-n1c2ccccc2c2cc(C)ccc21 ; "TD-2"] 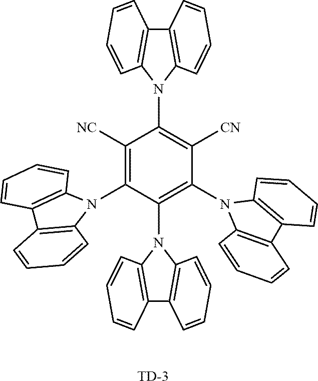 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; "TD-3"] 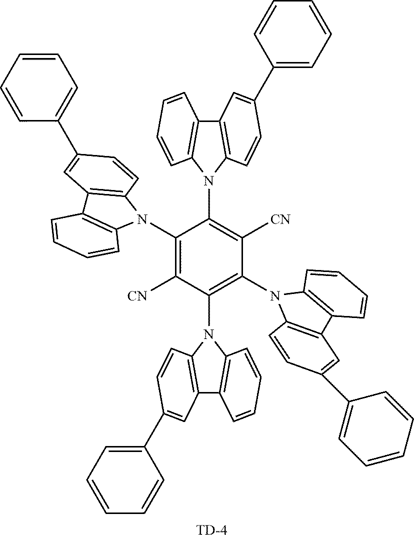 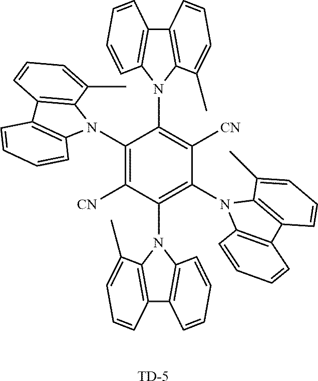 [SMILES: Cc1cccc2c3ccccc3n(-c3c(C#N)c(-n4c5ccccc5c5cccc(C)c54)c(-n4c5ccccc5c5cccc(C)c54)c(C#N)c3-n3c4ccccc4c4cccc(C)c43)c12 ; "TD-5"] 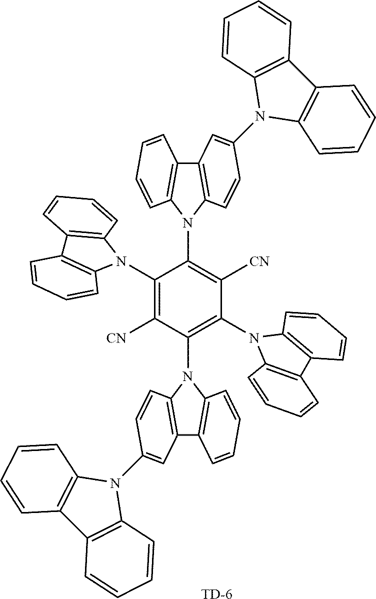 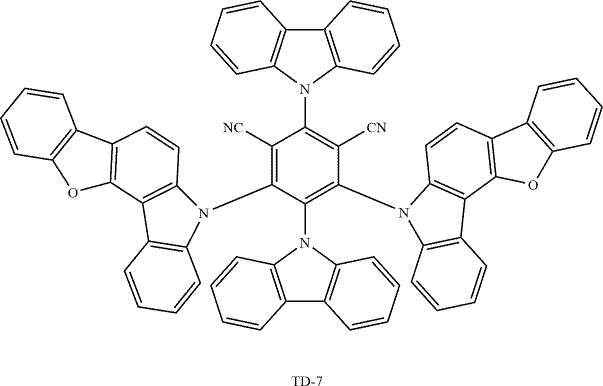 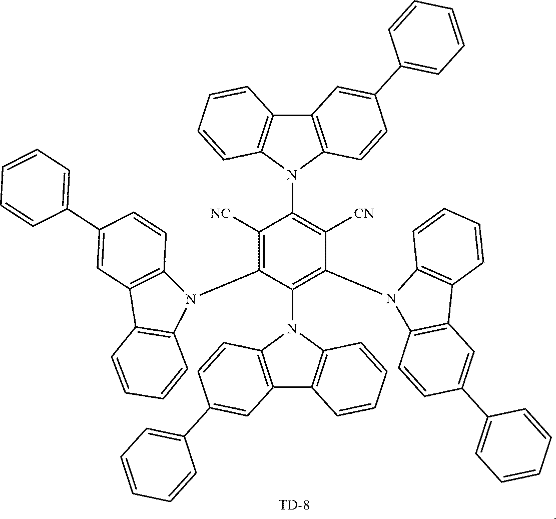
.

6. The organic light emitting diode according to claim 1, wherein the first emitting part further includes a first electron blocking layer between the first electrode and the first emitting material layer, and
wherein the first emitting material layer contacts the first electron blocking layer.

7. The organic light emitting diode according to claim 6, wherein the first emitting part further includes a first hole transporting layer between the first electron blocking layer and the first electrode, and a first electron transporting layer between the first hole blocking layer and the second electrode.

8. The organic light emitting diode according to claim 1, wherein a first weight % of the second compound in the first emitting material layer is greater than a second weight % of the second compound in the first intermediate functional layer.

9. The organic light emitting diode according to claim 8, wherein the first weight % is 40 or more, and the second weight % is 10 or less.

10. The organic light emitting diode according to claim 1, wherein the first emitting material layer has a first thickness, and the first intermediate functional layer has a second thickness being smaller than the first thickness.

11. The organic light emitting diode according to claim 10, wherein the second thickness is 40% or less of the first thickness.

12. The organic light emitting diode according to claim 11, wherein the second thickness is 100 Å or less.

13. The organic light emitting diode according to claim 1, wherein each of the first compound in the first emitting material layer and the first compound in the first intermediate functional layer is represented by Formula 1: 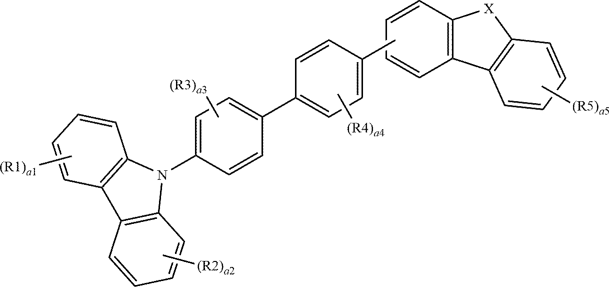
,
wherein each of R1, R2, R3, R4 and R5 is independently selected from the group consisting of a substituted or unsubstituted C1 to C10 alkyl group, a substituted or unsubstituted C6 to C30 arylene group and a substituted or unsubstituted C5 to C30 heteroarylene group,
each of a1, a2, a3, a4 and a5 is independently an integer of 0 to 4,
X is NR⁶, O or S, and
R⁶ is selected from the group consisting of hydrogen, a substituted or unsubstituted C1 to C10 alkyl group, a substituted or unsubstituted C6 to C30 arylene group and a substituted or unsubstituted C5 to C30 heteroarylene group.

14. The organic light emitting diode according to claim 13, wherein each of the first compound in the first emitting material layer and the first compound in the first intermediate functional layer is independently selected from compounds in Formula 2: 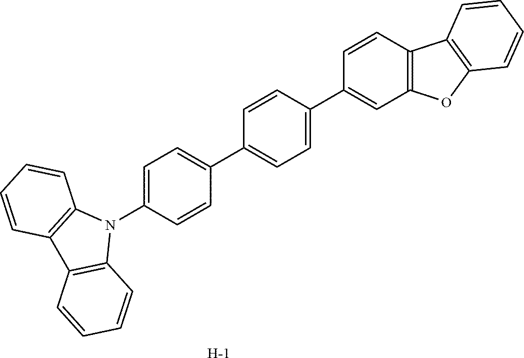 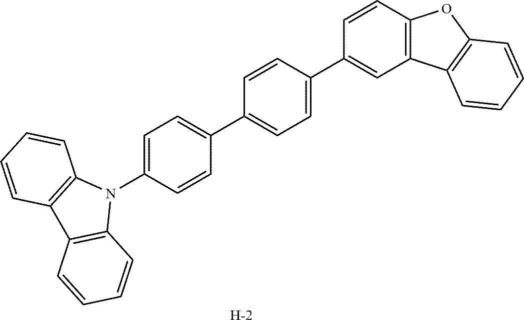 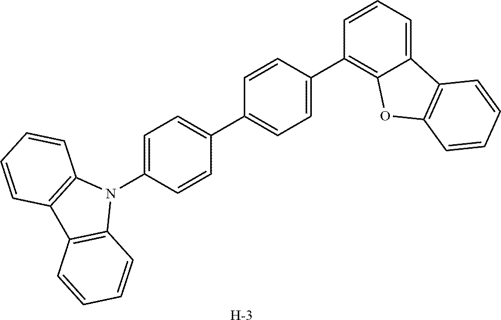 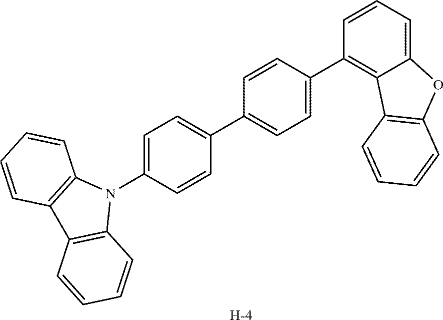 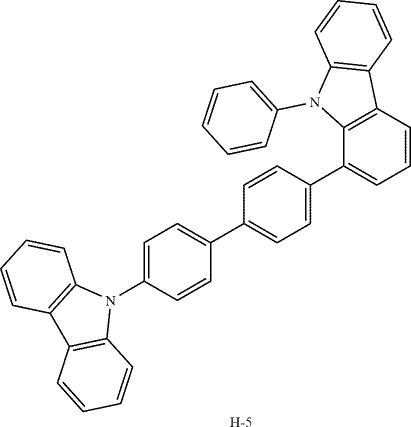 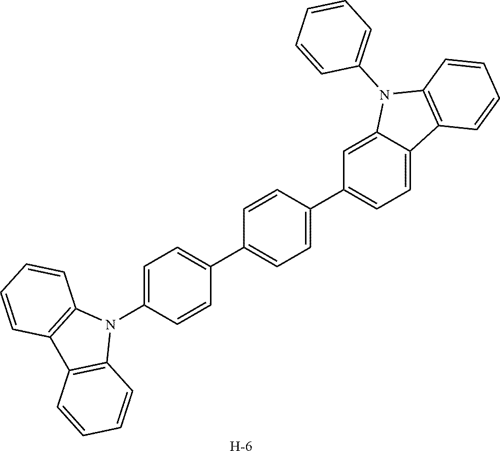 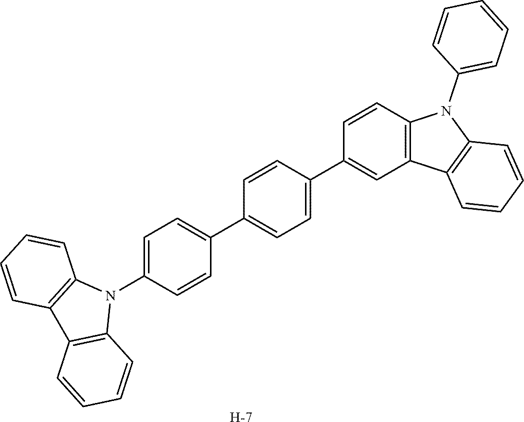 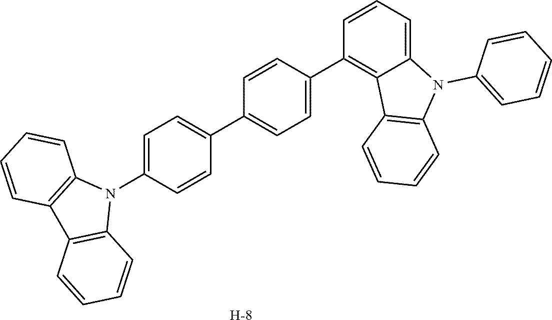 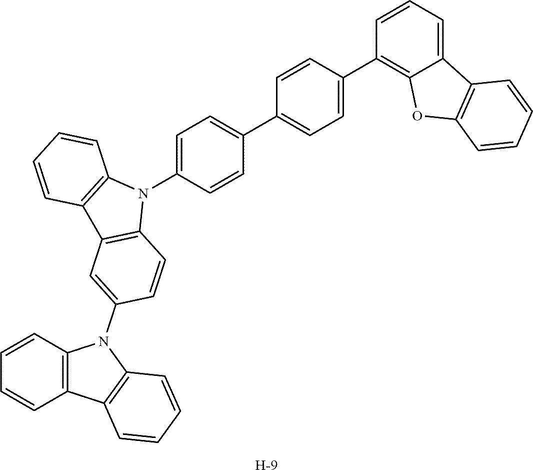 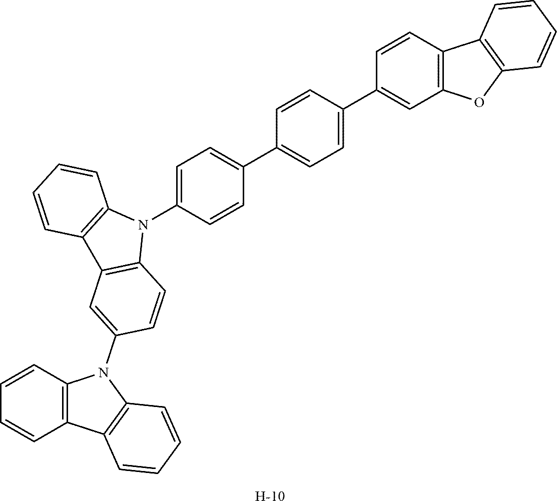 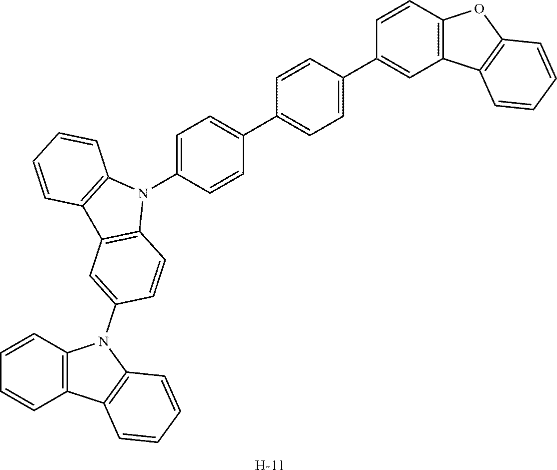 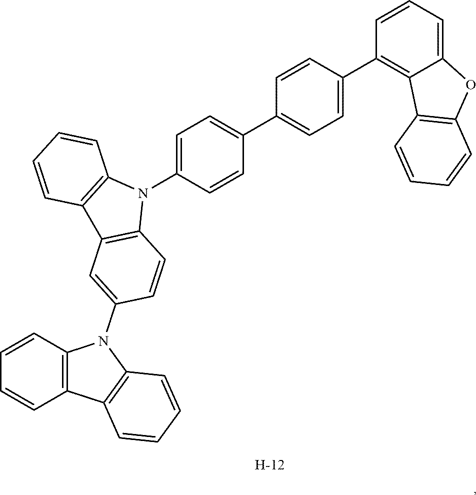
.

15. The organic light emitting diode according to claim 1, wherein the third compound is represented by Formula 5: 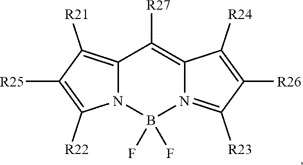
wherein each of R21, R22, R23 and R24 is independently selected from a substituted or unsubstituted C6 to C30 aryl group, and
each of R25, R26 and R27 is independently selected from the group consisting of hydrogen, deuterium, a substituted or unsubstituted C1 to C10 alkyl group, a substituted or unsubstituted C6 to C30 aryl group and a substituted or unsubstituted C5 to C30 heteroaryl group.

16. The organic light emitting diode according to claim 15, wherein the third compound is one of compounds in Formula 6: 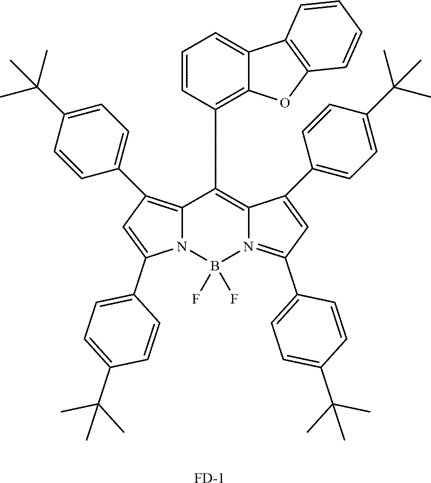 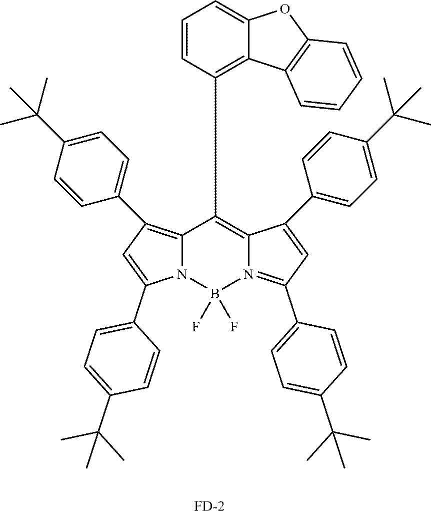 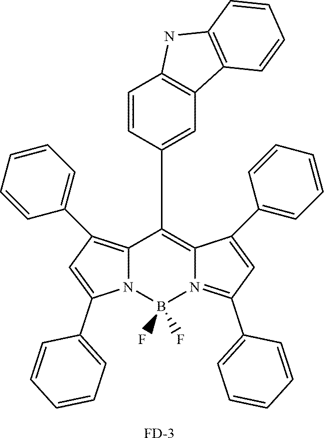 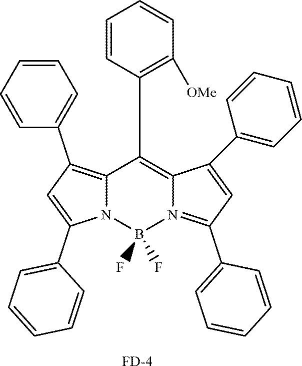 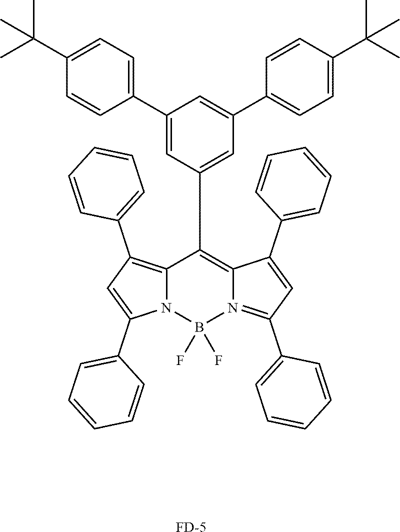 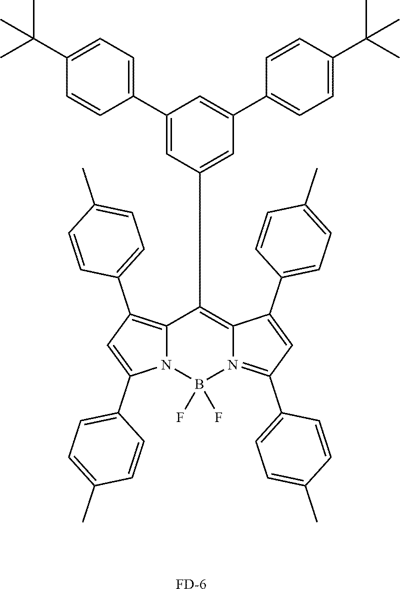
.

17. The organic light emitting diode according to claim 1, further comprising:
a second emitting part including a second emitting material layer, and positioned between the first emitting part and the first electrode or between the first emitting part and the second electrode; and
a charge generation layer between the first emitting part and the second emitting part,
wherein the second emitting material layer includes a fourth compound and a fifth compound.

18. The organic light emitting diode according to claim 17, wherein the fourth compound is a compound in Formula 12, and the fifth compound is a compound in Formula 13: 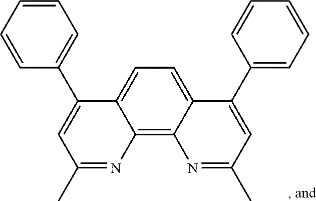 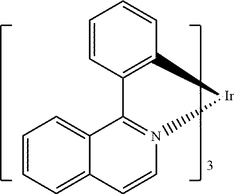
.

19. The organic light emitting diode according to claim 17, wherein the second emitting part further comprises:
a second hole transporting layer positioned at a first side of the second emitting material layer and contacting the second emitting material layer; and
a second electron transporting layer positioned at a second side of the second emitting material layer and contacting the second emitting material layer.

20. An organic light emitting display device, comprising:
a substrate including a red pixel region, a green pixel region and a blue pixel region; and
an organic light emitting diode disposed on the substrate and in the red pixel region, the organic light emitting diode including:
a first electrode;
a second electrode facing the first electrode; and
a first emitting part including a first emitting material layer between the first and second electrodes, a first hole blocking layer between the second electrode and the first emitting material layer, and a first intermediate functional layer between the first emitting material layer and the first hole blocking layer,
wherein the first emitting material layer includes a first compound, a second compound and a third compound, and the first intermediate functional layer includes a first compound and a second compound, and
wherein the second compound in the first intermediate functional layer has a core that is the same as the second compound in the first emitting material layer, and has a higher lowest unoccupied molecular orbital (LUMO) energy level than the second compound in the first emitting material layer.
